(19) United States
(12) Patent Application Publication
(10) Pub. No.: US 2012/0105087 A1
(43) Pub. Date: May 3, 2012

(54) APPARATUS FOR TESTING CIRCUIT BOARDS OF COMPUTING DEVICES AND METHODS FOR SAME

(76) Inventors: Gordon Mackenzie, Austin, TX (US); John A. Norton, Houston, TX (US); Thornton J. Bates, Houston, TX (US)

(21) Appl. No.: 12/938,941

(22) Filed: Nov. 3, 2010

(51) Int. Cl. G01R 31/00; G01R 31/304

(52) U.S. Cl. 324/750.03; 324/763.01; 324/756.01

(57) ABSTRACT

Embodiments provide apparatus for testing a primary PCB of a native computing device, the apparatus including a plurality of fixture mounting posts selectively positionable in alignment with mounting holes for the fixture mounting posts to be received in the mounting holes to support the primary PCB on the apparatus, and a fixture frame configured to support the plurality of fixture mounting posts in a plurality of selected mounting post locations, and embodiments provide methods for testing a primary PCB.

### FIELD OF INVENTION

This invention relates generally to apparatus for testing circuit boards of computing devices, and methods for same.

### BACKGROUND OF THE INVENTION

Computing devices can include one or more printed circuit boards (PCB's). “Computing device”, as the term is used herein, encompasses but is not limited to, the following: notebook computers, tablet computers, laptop computers, portable computers, handheld computing devices, and smartphones. In addition to the products identified in the preceding sentence, “computing device” also encompasses any computing device that includes at least one primary printed circuit board (“PCB”) and includes, is connected, or is connectable via at least one wired, or wireless, connection to a suitable user input device, such as a touchscreen or set of keys, and to a suitable user output device, such as a display.

A “primary PCB”, as the term is used herein, is the largest or primary PCB in a computing device, as determined by consideration of designated criteria, in comparison to any other PCB's located in the same computing device. It will be understood that relative size of PCB's can be measured by total cross-sectional area of the PCB, or the number or size of on-board electronic components supported by the PCB, or both of the preceding, or by any other criteria relevant to comparing PCB's located in the same computing device. A range of informal terminology can be used to reference primary PCB's included in computing devices, and informal terminology includes but is not limited to, the following terms: motherboard and main logic board (“MLB”). Computing devices include a primary housing which supports the primary PCB. The primary housing encloses at least a portion of the primary PCB to prevent damage to the same as a consequence of direct contact with the environment external of the primary housing.

For reasons stated below which will become apparent to those skilled in the art upon reading and understanding the present specification, there is a need in the art for improved test apparatus for testing disparate circuit boards of computing devices, and methods for same.

### BRIEF DESCRIPTION OF THE INVENTION

Various shortcomings, disadvantages and problems are addressed herein, which will be understood by one of ordinary skill upon reading and studying the specification. In one aspect, embodiments provide test apparatus for testing PCB's. In one aspect, embodiments provide methods for testing PCB's. In one aspect, embodiments provide test apparatus for testing primary PCB's of computing devices. In one aspect, embodiments provide methods for testing primary PCB's of computing devices. Apparatus and methods of varying scope are described herein. In addition to aspects and advantages described in the specification, further aspects and advantages will become apparent by reference to the drawings and by reading the detailed description that follows.

### BRIEF DESCRIPTION OF THE DRAWINGS

FIG. 1 is an elevated perspective view of an embodiment of test apparatus for testing a primary PCB.

FIG. 2 is an elevated perspective view of test apparatus according to an embodiment and generally shown in FIG. 1, with a primary PCB positioned to be mounted thereupon.

FIG. 3 is an elevated perspective view, similar to FIG. 2, with a transparent depiction of the primary PCB exposing hidden detail.

FIG. 4 is an enlarged, simplified partial view showing detail of an exemplary fixture mounting post of test apparatus according to an embodiment, in an area generally indicated by reference (4) in FIG. 3, with detail of nearby structure omitted for clarity.

FIG. 5 is an enlarged partial exploded view showing detail of the fixture mounting post of test apparatus depicted in FIG. 4.

FIG. 6 is an elevated perspective view similar to FIG. 2, showing test apparatus according to an embodiment with a primary PCB aligned thereupon during mounting, and with distal closures of a plurality of fixture mounting posts to be installed to secure the fixture mounting posts in corresponding mounting holes of the primary PCB.

FIG. 7 is an elevated perspective view, similar to FIG. 6, with a transparent depiction of the primary PCB exposing hidden detail.

FIG. 8 is an enlarged, simplified partial view showing detail of an exemplary fixture mounting post of test apparatus according to an embodiment, in an area generally indicated by reference (8) in FIG. 7, with detail of nearby structure omitted for clarity.

FIG. 9 is an elevated perspective view similar to FIG. 6, showing test apparatus according to an embodiment with a primary PCB mounted thereupon and a cooling air supply nozzle positioned to supply cooling air to a portion of the primary PCB.

FIG. 10 is an enlarged, simplified, partial schematic layer view of test apparatus according to an embodiment, generally showing a fixture mounting post and first alignment rail thereof supporting a primary PCB secured on the fixture mounting post, and taken generally along 10-10 in FIG. 9.

FIG. 11 is an elevated perspective view similar to FIG. 9, showing test apparatus according to an embodiment with a primary PCB mounted thereupon and a cooling air supply nozzle positioned to supply cooling air to a portion of the primary PCB, with a fixture frame of the test apparatus supported by a debug fixture base of the apparatus, and the fixture frame supported by the debug fixture base in an inclined, substantially vertical orientation.

FIG. 12 is elevated perspective view, similar to FIG. 11, with a transparent depiction of the primary PCB exposing hidden detail.

FIG. 13 is a side view of test apparatus according to an embodiment and taken generally along 13-13 in FIG. 11.

FIG. 14 is an elevated perspective view of test apparatus according to an embodiment and taken generally from a foreground end perspective indicated at 14-14 in FIG. 13.

FIG. 15 is elevated perspective view, similar to FIG. 14, with a transparent depiction of the primary PCB exposing hidden detail.

FIG. 16 is an elevated perspective view, similar to FIG. 11, showing test apparatus according to an embodiment with a primary PCB mounted thereupon and a cooling air supply nozzle positioned to supply cooling air to a portion of the primary PCB, with a fixture frame of the test apparatus occupying an inclined, substantially vertical orientation, and with the fixture frame of test apparatus according to an embodiment pivoted clockwise about forty-five (45) degrees relative to a vertical axis of a debug fixture base of test apparatus according to an embodiment.

FIG. 17 is an elevated perspective view of test apparatus according to an embodiment and taken generally from a foreground end perspective indicated at 17-17 in FIG. 13, but showing a fixture frame of test apparatus according to an embodiment being depicted upon being manually removed by an operator (not shown) from a debug fixture base of test apparatus according to an embodiment.

FIG. 18 is an enlarged, simplified partial view, similar to FIG. 8, showing detail of an exemplary fixture mounting post of test apparatus according to an alternative embodiment, with detail of nearby structure omitted for clarity.

FIG. 19 is a simplified schematic illustration of test apparatus according to an embodiment and including a cooling air supply configured to provide cooling air to a cooling air supply nozzle generally shown in FIG. 9.

FIG. 20 is a simplified schematic illustration of test apparatus according to an embodiment and having a primary PCB mounted thereon for testing, the test apparatus including a fixture frame, a plurality of replica peripherals, and a plurality of replica wired connections between a primary PCB and the replica peripherals, and with a debug fixture base omitted for clarity.

FIG. 21 is a simplified, enlarged partial view of test apparatus according to an embodiment and including an off-board replica battery and battery extension cable as generally shown in FIG. 20.

FIG. 22 is a simplified, enlarged partial view of an off-board replica battery and battery extension cable generally shown in FIG. 21.

FIG. 23 is a simplified perspective view, similar to FIG. 20, of test apparatus according to an alternative embodiment and including a fixture frame, a universal test fixture enclosure, a plurality of replica peripherals, and a plurality of replica wired connections between a primary PCB and the replica peripherals.

FIG. 24 is an exploded perspective view of test apparatus according to an alternative embodiment shown in FIG. 23 and including a universal test fixture enclosure.

FIG. 25 is an elevated perspective view, similar to FIG. 1, of an embodiment of test apparatus for testing a primary PCB, the test apparatus including a fixture frame supported on a support surface.

FIG. 26 is a simplified elevated perspective view of an embodiment of test apparatus shown generally in FIG. 25 and having a primary PCB mounted thereon for testing, the test apparatus including a fixture frame, a plurality of replica peripherals, and a plurality of replica wired connections between a primary PCB and the replica peripherals.

FIG. 27 is a simplified perspective view, similar to FIG. 26, of an embodiment of test apparatus shown generally in FIGS. 25-26 and having a primary PCB mounted on the fixture frame for testing, with the specific primary PCB illustrated in FIG. 27 being different from the specific primary PCB shown in FIG. 26, and the test apparatus including a different plurality of replica peripherals and replica wired connections corresponding to a different native computing device associated with the specifically illustrated primary PCB.

FIG. 28 is a flow chart illustrating a method for testing a primary PCB according to an embodiment.

### DETAILED DESCRIPTION OF THE INVENTION

In the following detailed description, reference is made to the accompanying drawings that form a part hereof, and in which is shown by way of illustration specific embodiments which may be practiced. These embodiments are described in sufficient detail to enable those skilled in the art to practice the embodiments, and it is to be understood that other embodiments may be utilized and that logical, mechanical, electrical and other changes may be made without departing from the scope of the embodiments. The following detailed description is, therefore, not to be taken in a limiting sense.

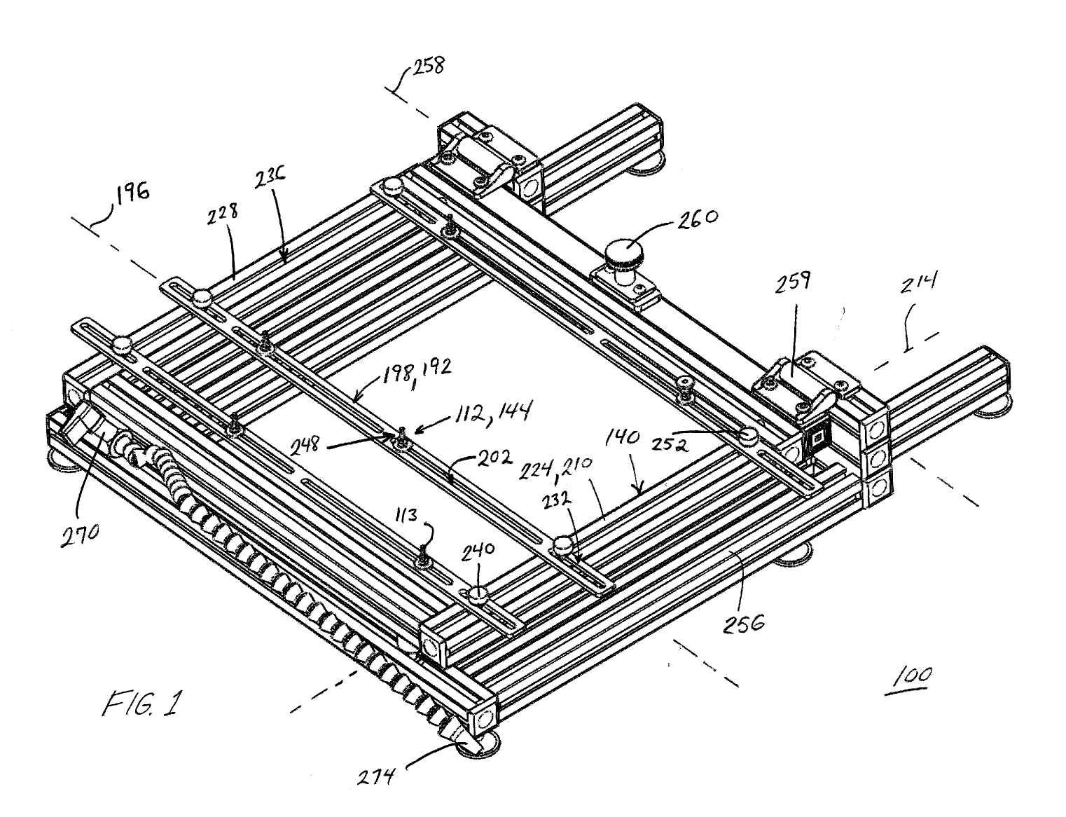

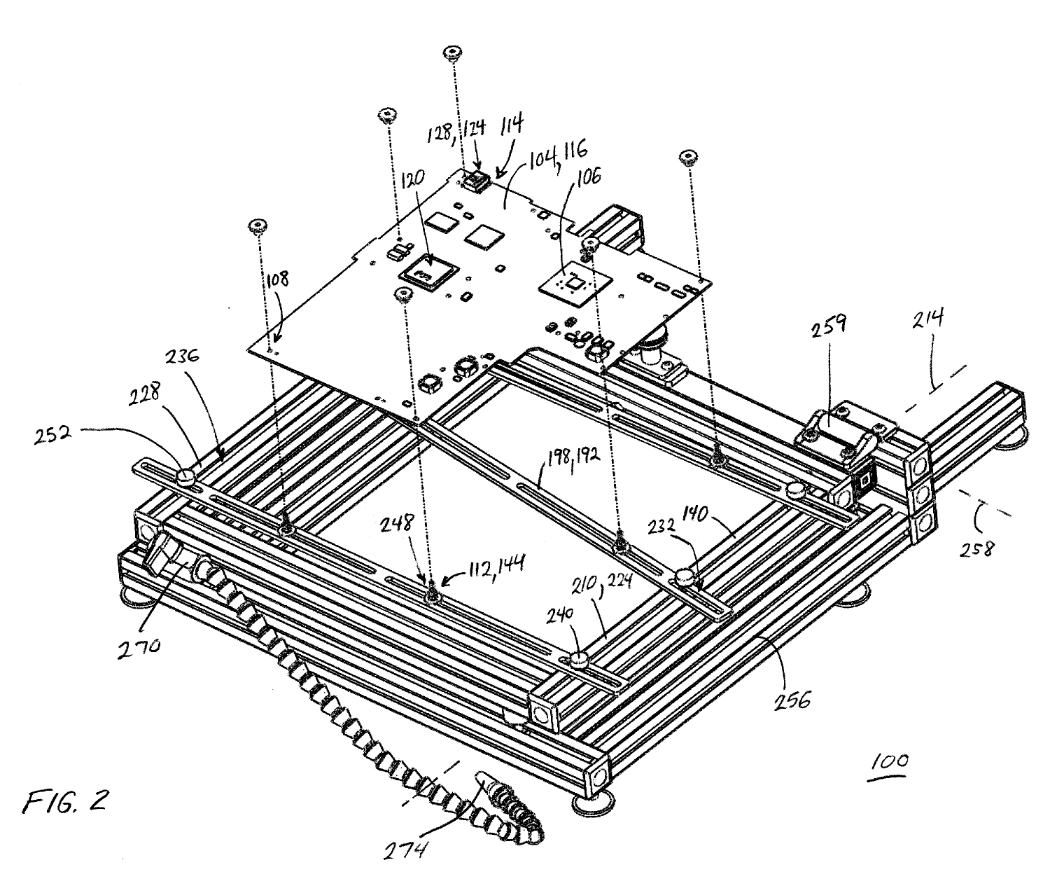

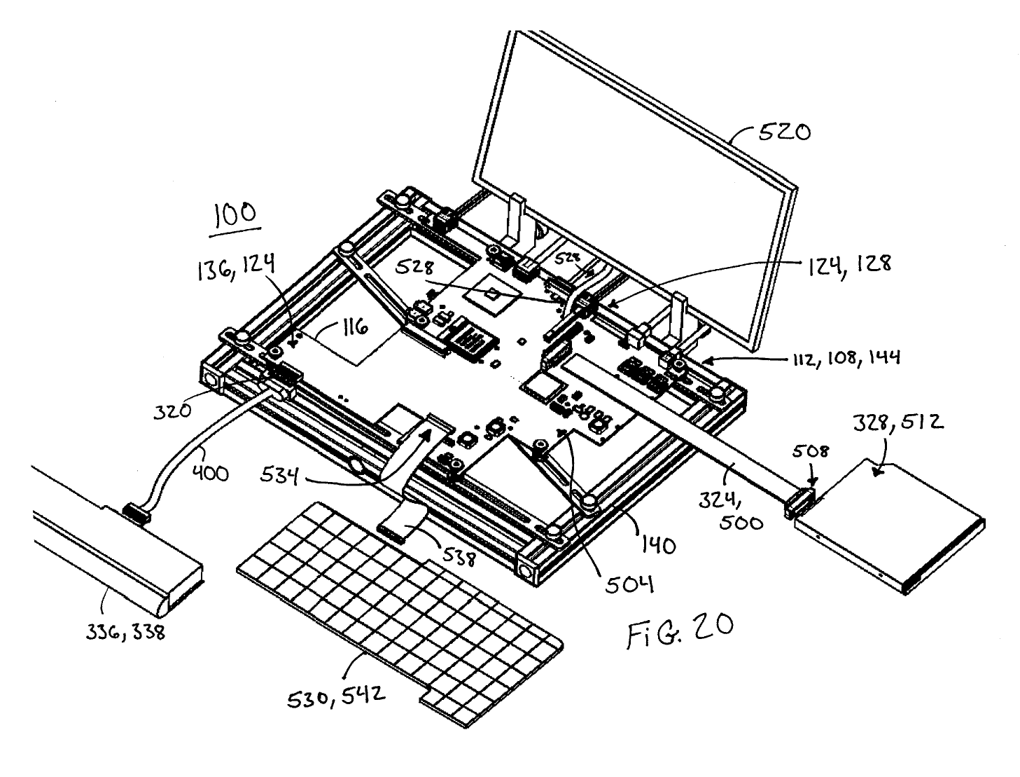

Illustrated in FIG. 1 is an embodiment of apparatus 100 for testing (hereinafter “test apparatus 100”) a primary PCB 104 (shown in FIG. 2) of a native computing device (not shown). It will be understood that, in the specific embodiment shown in FIG. 2, primary PCB 104 was resident in a native computing device before being removed therefrom for testing, and will be returned to an identical or similar native computing device (not shown) after testing if a defective condition of the primary PCB 104 is corrected, or if the primary PCB 104 is determined by testing to be in proper working condition. One of ordinary skill will understand that, according to embodiments (not shown) primary PCB's can be new and previously uninstalled in a particular native computing device. It will be understood that the native computing device (not shown) has a primary housing (not shown) configured to support therein the primary PCB 104 (shown in FIG. 2) during normal use of the native computing device (not shown). The primary housing (not shown) of the native computing device (not shown) includes a spaced plurality of mounts (not shown) arranged to engage the primary PCB 104 to support the same relative to the primary housing (not shown). The primary housing (not shown) includes at least one heat sink (not shown) or suitable thermal regulation system or device (not shown), such as a fan-powered cooling system or other active cooling system (not shown) suitable for regulating temperature of primary PCB 104 or at least one portion thereof. One of ordinary skill will understand that primary housing (not shown) can include a heat sink (not shown) for cooling primary PCB 104 at a processor 106 (shown in FIG. 2) mounted thereon, because operation of such a processor 106 can generate a substantial amount of heat requiring dissipation. Referring to FIG. 2, it can be observed that primary PCB 104 is removed from the primary housing (not shown) for testing of the primary PCB 104 on test apparatus 100. Test apparatus 100 lacks a housing to enclose the primary PCB 104, such that the primary PCB 104 is supported in an open environment. Referring to FIG. 2, the primary PCB 104 includes a plurality of spaced mounting holes 108 arranged in substantially planar spaced relation for receiving the plurality of mounts (not shown), and at least three of the plurality of mounting holes 108 are used to support primary PCB 104 on test apparatus 100. It will be understood that, in the embodiment illustrated in FIG. 1, at least three of the mounting holes 108 receive respective fixture mounting posts 112 of test apparatus 100, and that the fixture mounting posts 112 cooperate with the mounting holes 108 to support the primary PCB 104 on test apparatus 100 for testing the primary PCB 104. Primary PCB includes a circuit board 116 having defined therein the plurality of spaced mounting holes 108. In embodiments (not shown), one or more mounting hole extensions can be installed on circuit board 116 along respective edges thereof for respective of the mounting holes 108 to be provided in the mounting hole extensions in spaced relation to circuitry on circuit board 116, such that the mounting holes do not interfere with dense circuitry. It will be understood also, that mounting hole extensions can be mounted along respective edges of circuit board 116 and can accommodate minor vertical differences in the locations of one or more mounts (not shown) of the primary housing (not shown). For simplification, all mounting holes 108 of primary PCB will be described herein as existing in a common board plane 114 (shown in FIG. 2) defined by and coextensive with circuit board 116. Referring to FIG. 2, primary PCB 104 includes a plurality of electronic components 120 mounted on circuit board 116. Referring to FIG. 20, primary PCB 104 includes a plurality of interconnects 124 mounted on circuit board 116 or permanently connected to the same. The plurality of interconnects 124 are configured for engagement in mating relationship with a plurality of off-board mating connectors (not shown) each corresponding to respective of a plurality of off-board wired connections suitable to establish necessary electrical or data communications with corresponding off-board peripherals (not shown) of the native computing device (not shown). One of ordinary skill will understand that each of the plurality of interconnects 124 is disconnectable from the corresponding mating off-board connectors (not shown) for the primary PCB 104 to be removed from the primary housing (not shown) of the native computing device (not shown) for testing of the primary PCB 104 on test apparatus 100. One of ordinary skill will understand that a plurality of replica off-board display connectors (not shown) are provided at test apparatus 100 for establishing temporary replica wired connections from the on-board interconnects 124 of primary PCB 104 to a plurality of replica off-board peripherals (not shown). It will be understood that, at test apparatus 100, the replica off-board peripherals (not shown) and replica mating connectors (not shown) and replica intermediate wired connections there between are substantially identical to native off-board peripherals, native mating connectors and native wired connections. It will be understood that, in totality, the plurality of off-board peripherals (not shown) provide a replica off-board peripheral environment that replicates a native off-board peripheral environment (not shown) corresponding to the native computing device (not shown) at test apparatus 100 for replicating the environment of primary PCB 100 in a native computing device in connection with testing primary PCB 104. One of ordinary skill will understand that the plurality of interconnects 124 includes at least a display interconnect 128 configured for establishing a suitable wired or wireless connection to an off-board display (not shown). One of ordinary skill will understand that, among the plurality of replica off-board peripherals and replica wired connections thereto, an off-board replica display mating connector (not shown) is provided at test apparatus 100 for temporary mating engagement with a respective on-board display interconnect 128 of primary PCB 104 to establish communication with an off-board replica display (not shown) supported for viewing by an operator (not shown) of test apparatus 100 in connection with testing primary PCB 104. It will be understood that such replica display (not shown) can be provided power from primary PCB 104 or another suitable power source (not shown). One of ordinary skill will understand that, among the plurality of replica off-board peripherals and replica wired connections thereto, an off-board replica operator input device mating connector (not shown) is provided at test apparatus 100 for temporary mating engagement with a respective on-board display interconnect 132 of primary PCB 104 to establish communication with an off-board replica operator input device (not shown) supported for manual or similar use by an operator (not shown) of test apparatus 100 in connection with testing primary PCB 104. It will be understood that such replica operator input device (not shown) can be provided power from primary PCB 104 or another suitable power source (not shown). One of ordinary skill will understand that, among the plurality of replica off-board peripherals and replica wired connections thereto, an off-board replica battery mating connector (not shown) is provided at test apparatus 100 for temporary mating engagement with a respective on-board power supply interconnect or battery port 136 of primary PCB 104 to establish data communication and to provide power from an off-board replica battery (not shown) to primary PCB 104 supported on test apparatus 100 in connection with testing primary PCB 104. It will be understood that such replica battery (not shown) can include a data source to enable proper functioning of the replica battery (not shown) for providing power to primary PCB 104. It will also be understood that another suitable off-board replica power supply can be present.

One of ordinary skill will understand that test apparatus 100 is configured for receiving and testing in sequence a series of disparate primary PCB's 104 having a plurality of mounting holes 108 arranged and spaced in different configurations on circuit board 116. It will be understood that test apparatus 100 includes a plurality of movable, selectively positionable fixture mounting posts 116 for supporting each primary PCB 104 having mounting holes 108 arranged and space in different configurations. According to an embodiment illustrated in FIG. 2, test apparatus 100 comprises a plurality of fixture mounting posts 112 selectively positionable in alignment with the plurality of mounting holes 108 for the fixture mounting posts 112 to be received in the mounting holes 108 to support the primary PCB 104 on the test apparatus 100.

According to an embodiment illustrated in FIG. 1, test apparatus 100 comprises a fixture frame 140. Fixture frame 140 is configured to support the plurality of fixture mounting posts 112 in a plurality of changeable, selected mounting post locations 144. It will be understood that the mounting post locations 144 are changeable and selectable to coincide and align with at least three mounting hole locations 148 (shown in FIG. 2) of respective mounting holes 108 of respective primary PCB's 104 in a series of multiple, different primary PCB's 104 to be tested on test apparatus 100. Each mounting post location 144 is selectable by an operator to selectively locate the plurality of fixture mounting posts 112 on the fixture frame 140 in alignment with the plurality of mounting holes 108 when the primary PCB 104 is positioned adjacent to the fixture frame 140 with the fixture mounting posts 112 interposed there between.

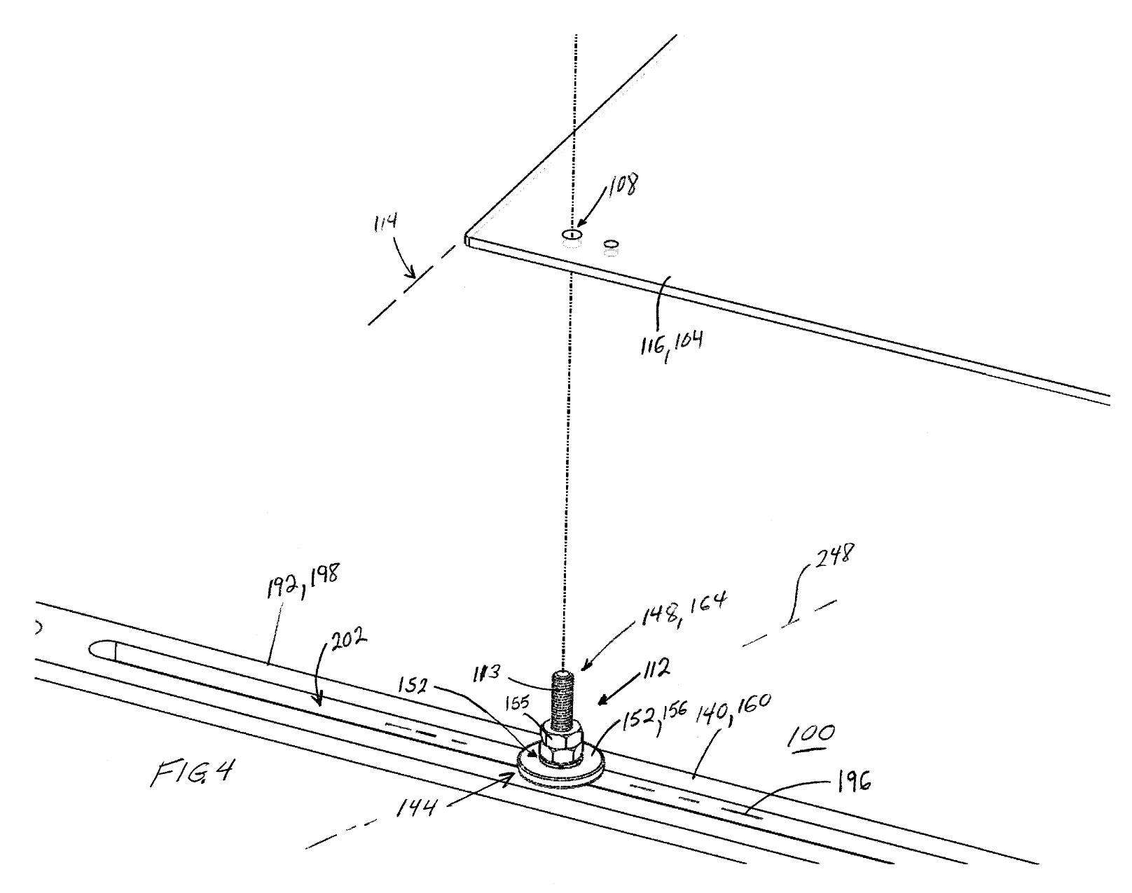

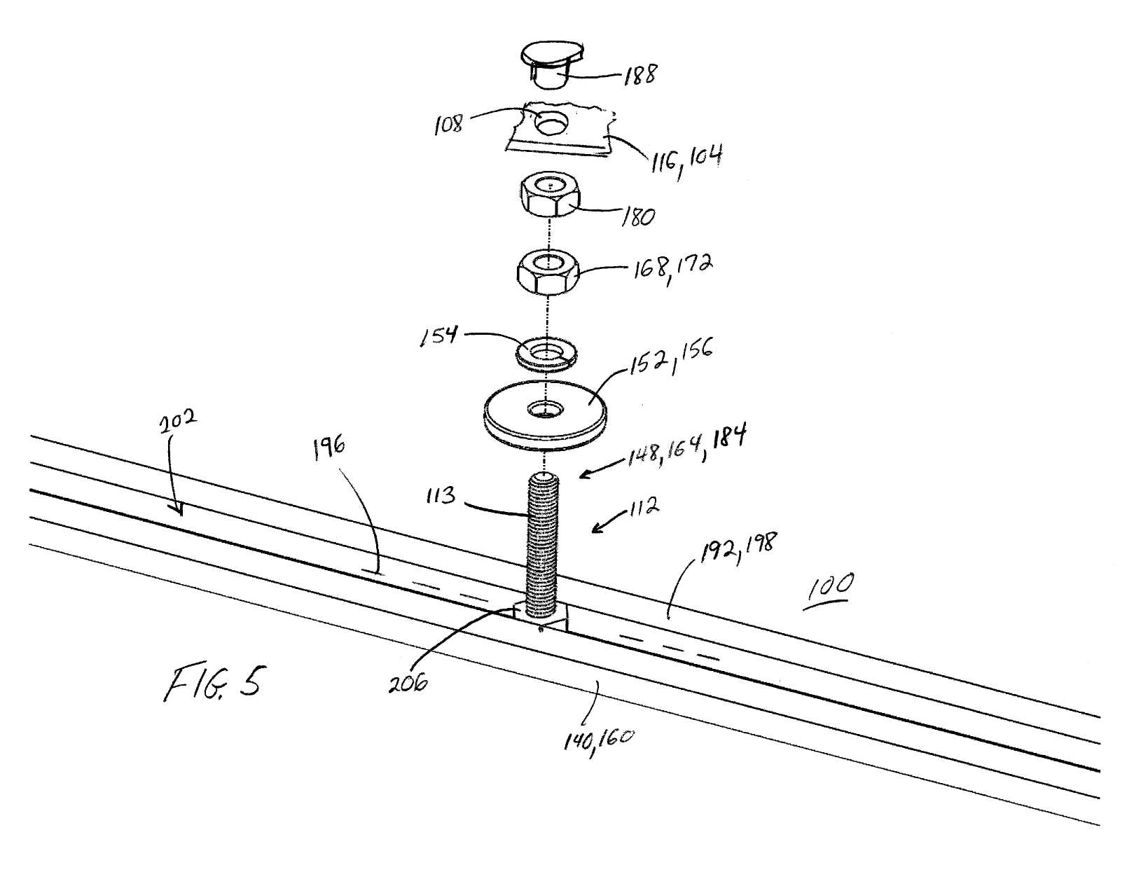

In an embodiment illustrated in FIG. 2 and best shown in FIGS. 4 and 5, test apparatus 100 comprises a plurality of fixture mounting posts 112 having a structure more particularly described herein. Each fixture mounting post 112 has a distal end 148 spaced apart from the fixture frame 140. The distal end 148 is configured to be received in a respective mounting hole 108 (see FIG. 4) of circuit board 116 of primary PCB 104 aligned therewith. Each fixture mounting post 112 has a base 152 spaced from the distal lend 148. Base 152 is configured for substantially fixed engagement with the fixture frame 140 in a selected mounting post location 144. Each fixture mounting post 112 is configured to be manually positioned on the fixture frame 140 in a selected mounting post location 144 by bringing the base 152 into substantially fixed engagement with the fixture frame 140 at a selected mounting post location 144. It will be understood that fixture frame 140 is configured to enable each fixture mounting post 112 to be manually positioned thereon and supported at any of a plurality of possible mounting post locations 144 that can be described in a two-dimensional, “x-y” plane having designated “x” axis and “y” axis coordinates, or the same physical location can also be described in terms of corresponding longitudinal and transverse coordinates or dimensions on fixture frame 140, as further disclosed herein. One of ordinary skill will understand that, as circuit board 116 is assumed to have a plurality of mounting holes 108 spaced apart only in a single plane identified herein as the “board plane” 114, it is unnecessary for fixture frame 140 to support the plurality of fixture mounting posts 112 in a third or “z axis” dimension. It will be understood, however, that fixture frame 140 can include elements, such as fixture mounting posts 112 of substantially different lengths for example, that allow the fixture frame 140 to receive and support a primary PCB 104 having mounting holes 108 located in multiple planes above or below the board plane 114.

According to an embodiment illustrated in FIG. 2, in test apparatus 100 each fixture mounting post 112 is configured to be retained in substantially fixed engagement with the fixture frame 140 at a corresponding selected mounting post location 144. Each fixture mounting post 112 is manually removable by an operator from substantially fixed engagement with the fixture frame 140 for the operator to relocate the same to different selected mounting post locations 144 corresponding to each next one of other primary PCB's 104 to be supported and tested on test apparatus 100. One of ordinary skill will understand that, according to an embodiment shown in FIG. 1 and FIG. 2, test apparatus 100 includes a fixture frame 140 supporting a plurality of fixture mounting posts 112 to be selectively positioned, by an operator, in a mounting plane or “x-y” plane for the fixture mounting posts 112 to be aligned with a series of differently configured mounting holes 108 of different primary PCB's 104 that are received, supported and tested on fixture frame 140. It will be understood, also, that in a specific embodiment shown in FIGS. 1 and 2, the fixture mounting posts 112 are supported on fixture frame 140 in a manner that enables the location or position of each fixture mounting post 112 in the mounting plane or “x-y” plane to be changed or varied in an incremental, non-discreet, or continuous manner. One of ordinary skill will understand that in specific embodiments, such as the specific embodiments illustrated in FIGS. 1 and 2, the potential locations of each fixture mounting post 112 in the mounting plane or “x-y” plane thus are not limited to discreet locations or positions. According to embodiments, not shown, the locations of each fixture mounting post 112 can be restricted to discreet locations in the mounting plane or “x-y” plane that correspond to discreet locations on fixture frame 140. According to an embodiment illustrated in FIG. 1, in test apparatus 100 each fixture mounting post 112 is configured to be attracted against the fixture frame 112 by magnetic forces to facilitate substantially fixed engagement there between. More particularly, in an embodiment illustrated in FIG. 1, test apparatus 100 includes fixture mounting posts 112 having a base 152 configured for substantially fixed engagement with the fixture frame 140, wherein the base 152 is configured to be attracted against the fixture frame 140 by magnetic forces to facilitate substantially fixed engagement there between. Particularly, in a specific embodiment illustrated in FIG. 1 and best shown in FIG. 4, test apparatus 100 comprises each fixture mounting post 112 having a base 152 including or formed of magnetic material 156, and fixture frame 140 including or formed of ferromagnetic material 160 at least in proximity to base 152 of each fixture mounting post 112. In the specific embodiment shown in FIG. 4, magnetic material 156 is a rare earth magnetic material providing for each base 152 a total magnetic force of about twelve (12) pounds against ferromagnetic material 160 when located against the same. In the specific embodiment illustrated in FIG. 4, ferromagnetic material 160 is steel.

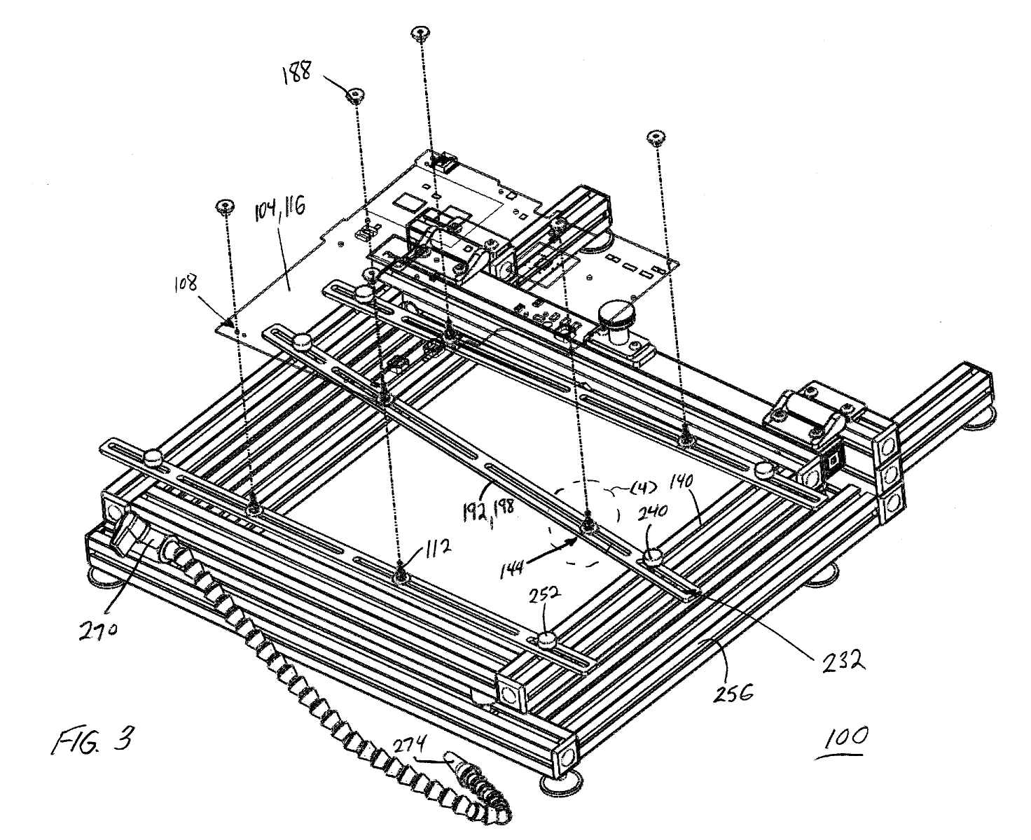

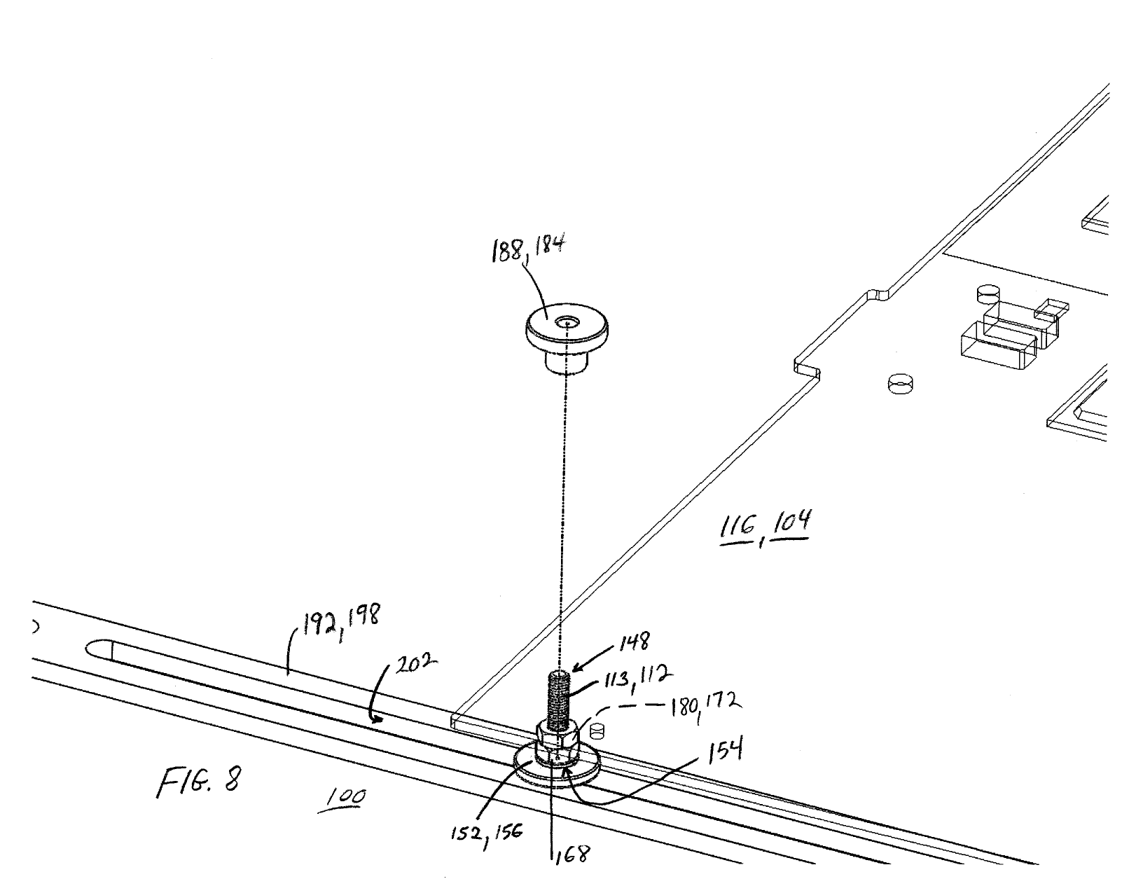

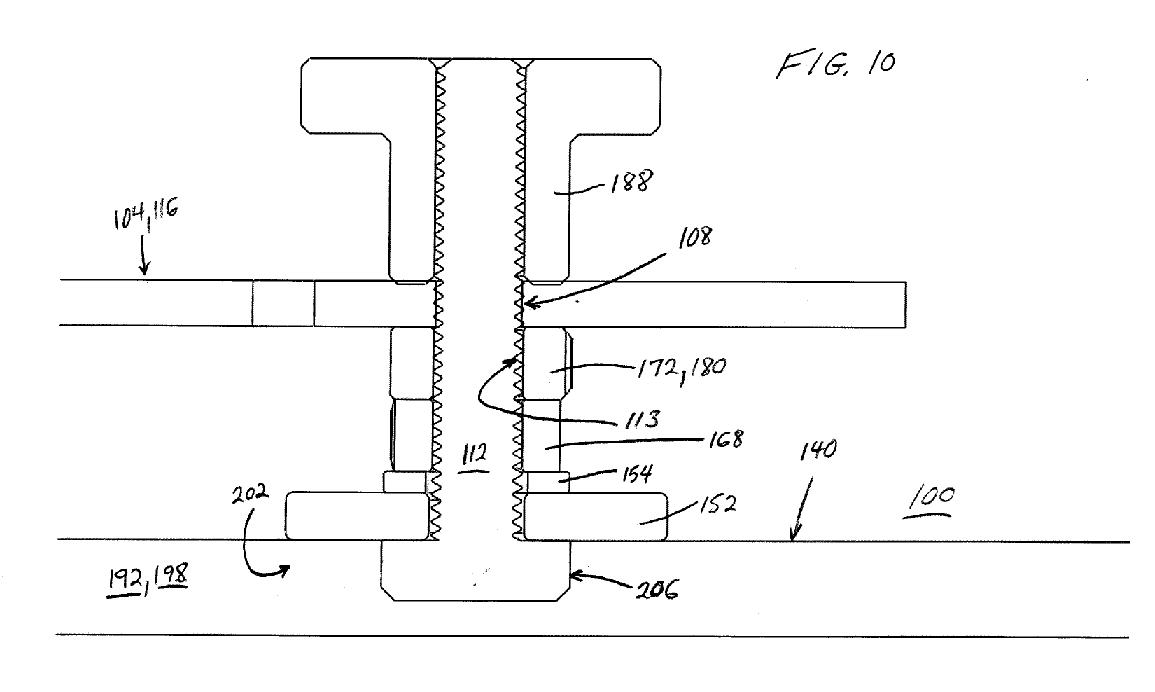

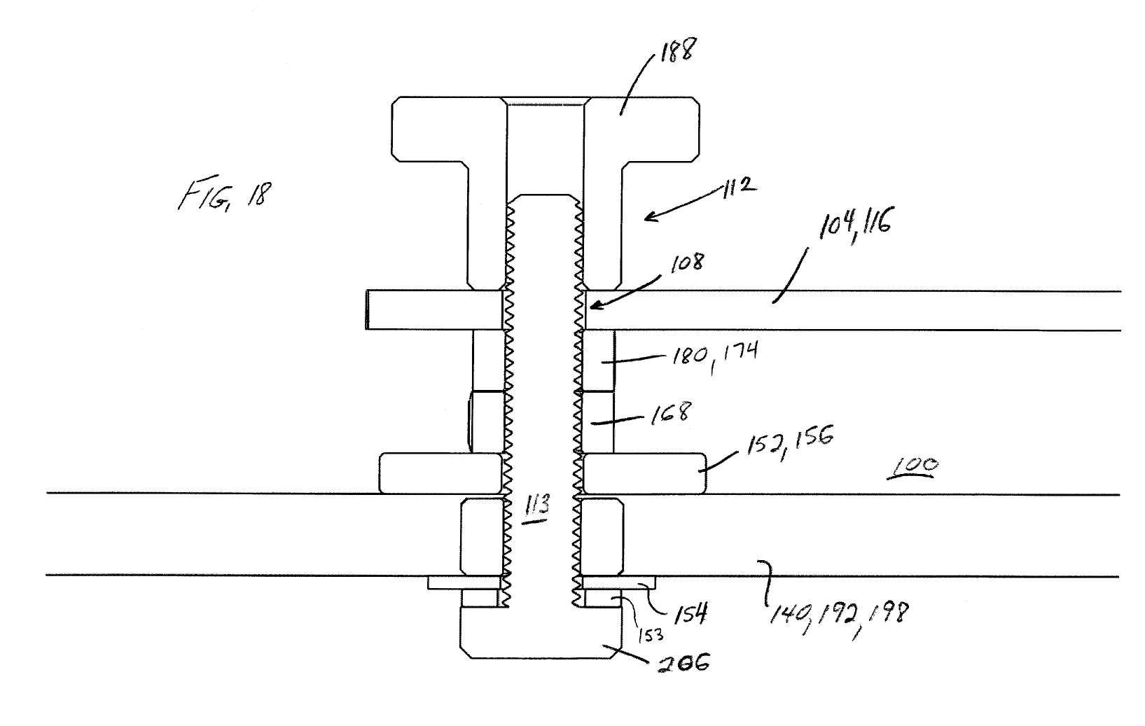

According to an embodiment illustrated in FIG. 1 and best shown in FIG. 4, test apparatus 100 comprises each fixture mounting post 112 at the distal end 148 thereof being formed of nonmagnetic material 164. Each fixture mounting post 112 having nonmagnetic material 164 forming distal end 148 thereof is configured for supporting the primary PCB 104 apart from the base 152, such that only nonmagnetic material 164 is located adjacent the primary PCB 104 to substantially avoid exposing the primary PCB 104 to the magnetic forces drawing the base 152 formed of magnetic material 164 against the fixture frame 140 formed of ferromagnetic material 160. According to an embodiment illustrated in FIG. 1 and best shown in FIG. 4, test apparatus 100 comprises each fixture mounting post 112 including an inner barrier material 168 positioned between the base 152 formed of magnetic material 156 and distal end 148 formed of nonmagnetic material 164 to prevent contact between primary PCB 104 and to substantially prevent communication of magnetic forces and magnetic currents from the base 152 to the primary PCB 104, and the inner barrier material 168 includes or is formed of substantially nonmagnetic material 164. It will be understood that substantially nonmagnetic material 164 substantially prevents magnetic forces and magnetic currents from acting on primary PCB 104. Thus, according to an embodiment illustrated in FIG. 1 and best shown in FIG. 4, test apparatus 100 comprises each fixture mounting post 112 including an inner barrier material 168 positioned between the base 152 and distal end 148, the inner barrier material 168 being substantially nonmagnetic to substantially prevent communication of magnetic forces and magnetic currents from the base 152 to the primary PCB 104. According to an embodiment illustrated in FIG. 18, test apparatus 100 comprises each fixture mounting post 112 including a plurality of barrier layers 176 each formed of nonmagnetic barrier materials 172 and positioned between the base 152 formed of magnetic material 156 and distal end 148 formed of nonmagnetic material 164, and between the fixture frame 140 formed of ferromagnetic material 160 and distal end 148 to isolate primary PCB 104 from substantial magnetic forces. It will be understood that, in the specific embodiment of test apparatus 100 illustrated in FIG. 18, the plurality of barrier layers 176 includes inner barrier material 168 and outer barrier material 180, and both are substantially nonmagnetic to substantially prevent communication of magnetic forces between the primary PCB 104 and fixture mounting post 112 and fixture frame 140 supporting the same. It will be understood that barrier layers 176 are conductive of electricity for establishing a connection to ground. It will be understood that leaking or delivering electric current to or from circuitry or electronic components 120 on circuit board 116 is avoided by the fixture mounting posts 112 being sized to avoid contacting the same. In a specific embodiment shown in FIGS. 1 and 4, both the inner barrier material 168 and outer barrier material 180 are formed by respective brass nuts 155 (FIG. 4) having internal threads for mating engagement with external threads of a fixed post member 113 of the fixture mounting posts 112. According to a specific embodiment (shown in FIG. 4), each fixture mounting post 112 includes a lock washer 154 positioned between base 152 and inner barrier material 168 or brass nut to prevent loosening of threaded components mounted on fixed post member 113. In an embodiment illustrated in FIG. 1 and best shown in FIG. 4, test apparatus 100 comprises the distal end 148 being formed of nonmagnetic material 164 which is, more particularly, non-ferrous alloy material 184. According to an embodiment illustrated in FIG. 4, test apparatus 100 comprises each fixture mounting post 112, between the base 152 formed of magnetic material 156 and the distal end 148 formed of non-ferrous alloy material 148, is formed of non-ferrous alloy material 148. According to an embodiment illustrated in FIG. 1 and as perhaps best shown in FIG. 2, test apparatus 100 comprises each fixture mounting post 112 including a distal retaining member 188. Distal retaining member 188 is removably installed at the distal end 148 to prevent inadvertent dislocation of the primary PCB 104 from the fixture mounting post 112, and the distal retaining member 188 is formed of nonmagnetic material 164. According to an embodiment illustrated in FIG. 4, test apparatus 100 comprises the distal retaining member 188 formed of non-ferrous alloy material 184. Although different non-ferrous alloy materials 184 can be used, in a specific embodiment illustrated in FIG. 1, the non-ferrous alloy material 184 is stainless steel. In the specific embodiment illustrated in FIGS. 1-5, fixed post member 113 at the distal end 148 has external threads, and distal retaining member 188 includes internal threads, to facilitate mating engagement between the same. Distal retaining member 188 having internal threads can be a suitable threaded cap formed of stainless steel. Threaded post member 113 can be a suitable threaded bolt formed of stainless steel. Lock nut 152 can be formed of stainless steel. In an arrangement shown in FIG. 18, lock washer 154 is located below fixture frame 140 and adjacent a third barrier layer 153. Referring to FIG. 8, it will be understood that distal end 148 defined by threaded fixed post member 113 is received in respective mounting hole 108 of circuit board 116 of primary PCB 104. It will be understood that the plurality of barrier layers 172 defined by corresponding brass nuts threaded on fixed post member 113 also provide clearance or stand-off spacing between primary PCB 104 and fixture frame 140. Referring to FIG. 10, the clearance or stand-off spacing is visible between primary PCB 104 and first locating member 192 defined by first locating rail 198 of fixture frame 140.

Referring to FIGS. 1-3, according to an embodiment illustrated therein, test apparatus 100 comprises the fixture frame 140 including a plurality of first locating members 192. In a specific embodiment illustrated in FIG. 1 and FIG. 2, the plurality of first locating members 192 numbers three (3). In other embodiments, more of the first locating members 192 can be present. The first locating members 192 are configured to support the plurality of fixture mounting posts 112. More particularly, in a specific embodiment, each of the first locating members 192 provides for a respective fixture mounting post 112 one degree of freedom for the fixture mounting post 112 to be selectively positioned along a mounting location first axis 196 (i.e., “x-axis”). Particularly, each first locating member 192 is configured for an operator manually to selectively locate a respective fixture mounting post 112 thereupon at a selected location or position on the mounting location first axis 192, wherein the selected mounting post location 144 or position of the fixture mounting post 112 along the mounting location first axis 196 corresponds to a respective mounting hole location 108, such that the selected mounting post location 144 or position of the fixture mounting post 112 on the mounting location first axis 192 is in alignment with a corresponding one of the plurality of mounting holes 108 when the primary PCB 104 is positioned adjacent to the fixture frame 140 with the fixture mounting posts 112 supported on respective of the first locating members 192 and thus interposed there between.

According to an embodiment illustrated in FIG. 1 and FIG. 2, test apparatus 100 comprises for fixture frame 140 each first locating member 192 including or being substantially formed by a respective elongated first rail member 198. Each first rail member 198 is supported by fixture frame 140, of which the first rail member 198 forms a portion thereof, to extend substantially along the mounting location first axis 196. It will be understood that each of the first rail members 198 is configured to support a corresponding fixture mounting post 112 at any of a plurality of selected mounting post locations 144 positioned incrementally, continuously or non-discreetly along the corresponding mounting location first axis 196 and in alignment with a respective mounting hole 108. Further, according to a specific embodiment illustrated in FIG. 1 and FIG. 2, test apparatus 100 comprises each elongated first rail member 198 having or including a respective elongated, open first alignment channel 202 defined in the first rail member 198. The first alignment channel 202 extends substantially along the mounting location first axis 196. Each fixture mounting post 112 has an alignment portion 206 (shown in FIG. 5) configured to be received in the first alignment channel 202 for locating or aligning the fixture mounting post 112 on the first rail member 198 at any of a plurality of selected locations along the mounting location first axis 196 and thereafter keeping the fixture mounting post 112 in alignment with the same by opposing inadvertent displacement of the alignment portion 206 from the first alignment channel 202.

According to an embodiment illustrated in FIG. 1 and FIG. 2, test apparatus 100 comprises the fixture frame 140 including a spaced pair of identical second locating members 210 extending in parallel relation and configured to support the plurality of first rail members 198 defining respective of the first locating members 192. Cooperation of the spaced, parallel second locating members 210 provides for each of opposite ends 232 of the plurality of first rail members 198 defining a respective first locating member 192 one degree of freedom for the same to be selectively positioned along a mounting location second axis 214 (i.e., “y” axis). The pair of parallel second locating members 210 is configured for an operator to selectively locate each of the opposite ends 232 of first rail member 198 defining a respective first locating member 192 thereupon at a corresponding selected location on the mounting location second axis 214. Each corresponding selected location on the mounting location second axis 214 corresponds to a respective mounting hole location 108. Each selected location of a first rail member 198 defining a respective first locating member 192 along the mounting location second axis 214 is aligned with a location on the mounting location second axis 214 of a corresponding one of the plurality of mounting holes 108 when the primary PCB 104 is positioned adjacent to the fixture frame 140 with the fixture mounting posts 112 interposed there between. It will be understood that, in the specific embodiment illustrated in FIGS. 1 and 2, each of the fixture mounting posts 112 is supported in alignment with a respective mounting hole 108, with each fixture mounting post 112 being supported on a corresponding one of the first rail members 198 defining a respective first locating member 192 at a selected fixture post location 220 located along the mounting location first axis 196 and with each of the first rail members 198 defining respective of first locating members 192 supported by the spaced pair of parallel second locating members 210, each of the second locating members 210 being located along a respective mounting location second axis 214 at a location corresponding to a respective mounting hole 108, such that each fixture mounting post 112 is interposed between the primary PCB 104 and fixture frame 140.

According to an embodiment illustrated in FIG. 1 and FIG. 2, test apparatus 100 comprises each second locating member 210 defined by a respective elongated second rail member 224 and supported to extend substantially along a respective mounting location second axis 214. In the specific embodiment illustrated in FIG. 1 and FIG. 2, a spaced pair of parallel, identical second rail members 224 defines opposite side members 228 of a fixed rectangular fixture frame 140. Each of the second rail members 224 is configured to support one of the opposite ends 232 of each of the plurality of first rail members 198 defining the first locating members 192 at any of a plurality of selected locations along a respective mounting location second axis 214. Each of the plurality of first locating members 192 has a corresponding fixture mounting post 112 supported thereon, as described elsewhere herein. It will be understood that fixture frame 140 includes a spaced pair of intermediate cross members 229 extending between the pair of opposed side members 228 and fixing the same in spaced parallel relation.

According to an embodiment illustrated in FIG. 1 and FIG. 2, test apparatus 100 comprises each elongated second rail member 224 having or including a respective elongated, open second locating channel 236 defined in the second rail member 224. The second locating channel 236 extends substantially along the mounting location second axis 214 of each of the respective second rail members 224. Each of the second rail members 224 is configured to support one of the opposite ends 232 of each of the plurality of first rail members 198 defining the first locating members 192 and positioned along the second locating channel 236 at any of a plurality of selected locations of a corresponding fixture mounting post 112 along the mounting location second axis 214. According to a specific embodiment illustrated in FIGS. 1 and 2, test apparatus 100 thus comprises the fixture frame 140 including a pair of identical second rail members 224 extending in spaced, parallel relation to support the plurality of first locating members 192 at opposite ends 232 thereof. According to an embodiment illustrated in FIGS. 1 and 2, test apparatus 100 comprises the mounting location second axis 214 extending in substantially perpendicular relationship to the mounting location first axis 196, such that cooperation of the mounting location second axis 214 with the mounting location first axis 196 defines a fixture mounting plane 238. Each of the second locating channels 236 defined in a respective second rail member 224 receives a plurality of secondary releasable fastening devices 240 each corresponding to a respective one of the plurality of opposite ends 232 of a respective first rail member 198 defining each first locating member 192. Each of the plurality of secondary releasable fastening devices 240 is selectively movable along the respective secondary locating channel 236 in common with a respective ends 232 of corresponding of the first rail members 198 each defining a respective first locating member 192. Each of the secondary releasable fastening devices 240 is manually releasably engageable for releasably fastening in a selected location along the mounting location second axis 214 a corresponding end 232 of a first rail member 198 defining a first locating member 192. It will be understood that, in a specific embodiment illustrated in FIGS. 1 and 2, the primary PCB 104 has a board plane 114 having therein the plurality of mounting holes 108. The fixture frame 140 has a fixture mounting plane 248 (see FIG. 4) having therein and defined by the plurality of fixture mounting posts 112. In the specific embodiment illustrated in FIGS. 1 and 2, the fixture mounting plane 248 extends in substantially parallel relationship with the board plane 114 when the primary PCB 104 is positioned adjacent to the fixture frame 140 with the fixture mounting posts 112 interposed there between and received in corresponding of the mounting holes 108.

According to an embodiment illustrated in FIGS. 1 and 2, test apparatus 100 comprises a plurality of secondary releasable fastening devices 240 each releasably engageable for selectively positioning a respective first rail member 198 on a respective second rail member 224 at a selected location on the mounting location second axis 214. According to an embodiment illustrated in FIGS. 1 and 2, test apparatus 100 comprises each secondary releasable fastening device 240 including and defined by a threaded fastener assembly 252. According to a specific embodiment illustrated in FIGS. 1 and 2, test apparatus 100 comprises a plurality of pairs of secondary releasable fastening devices 240 each received in a respective second locating channel 236 and releasably engageable for selectively positioning opposite ends 232 of a corresponding plurality of first rail members 198 defining first locating members 192 on a respective pair of second rail members 224. In the specific embodiment illustrated in FIGS. 1-2, each threaded fastener assembly 252 has a head thereof located in respective channel 236, a threaded post extending upward out of the channel 236, and a threaded cap nut that is releasable for manually sliding the respective end 232 of first rail member 198 relative to y-axis 214 and tightenable for fixing the same in a selected location along the y-axis 214.

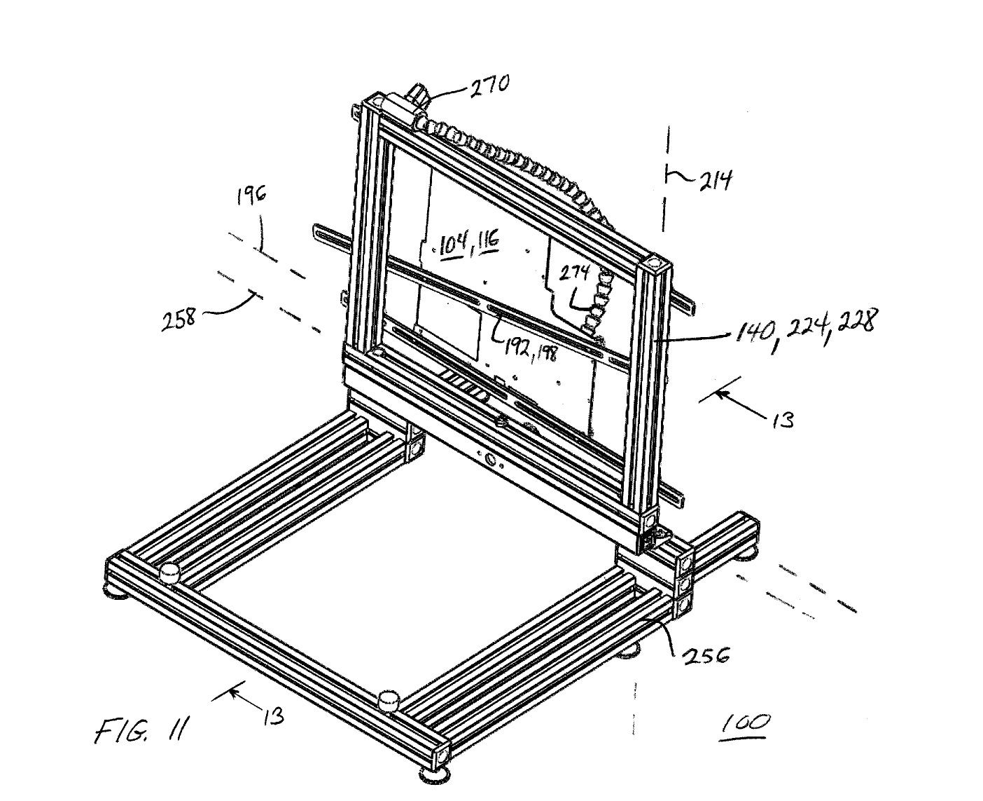

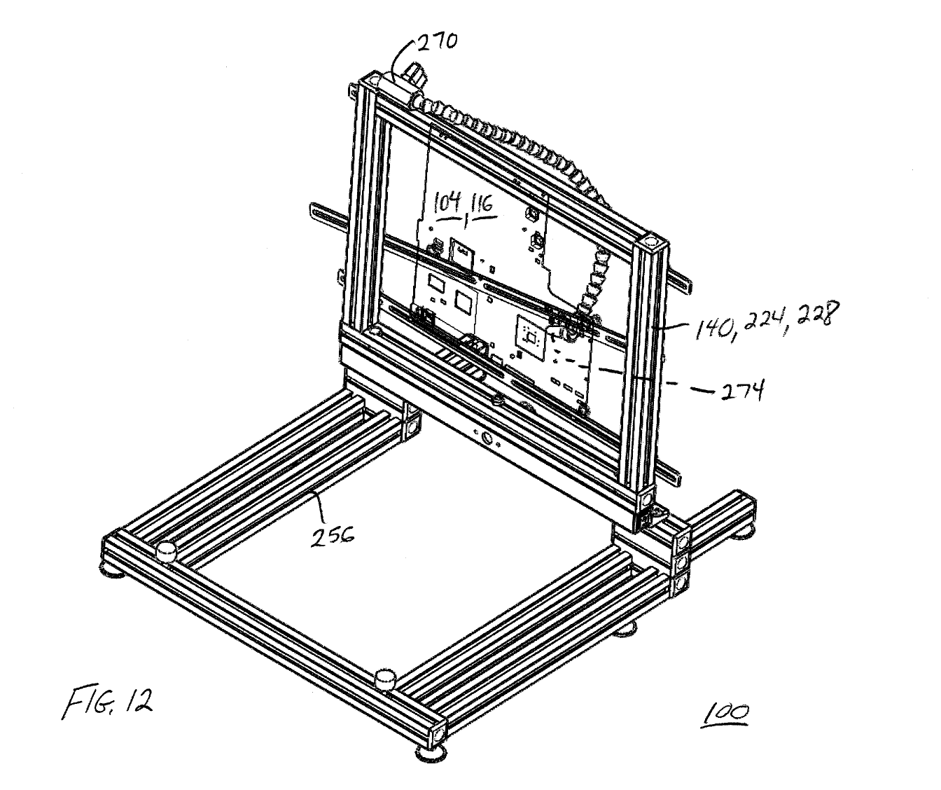

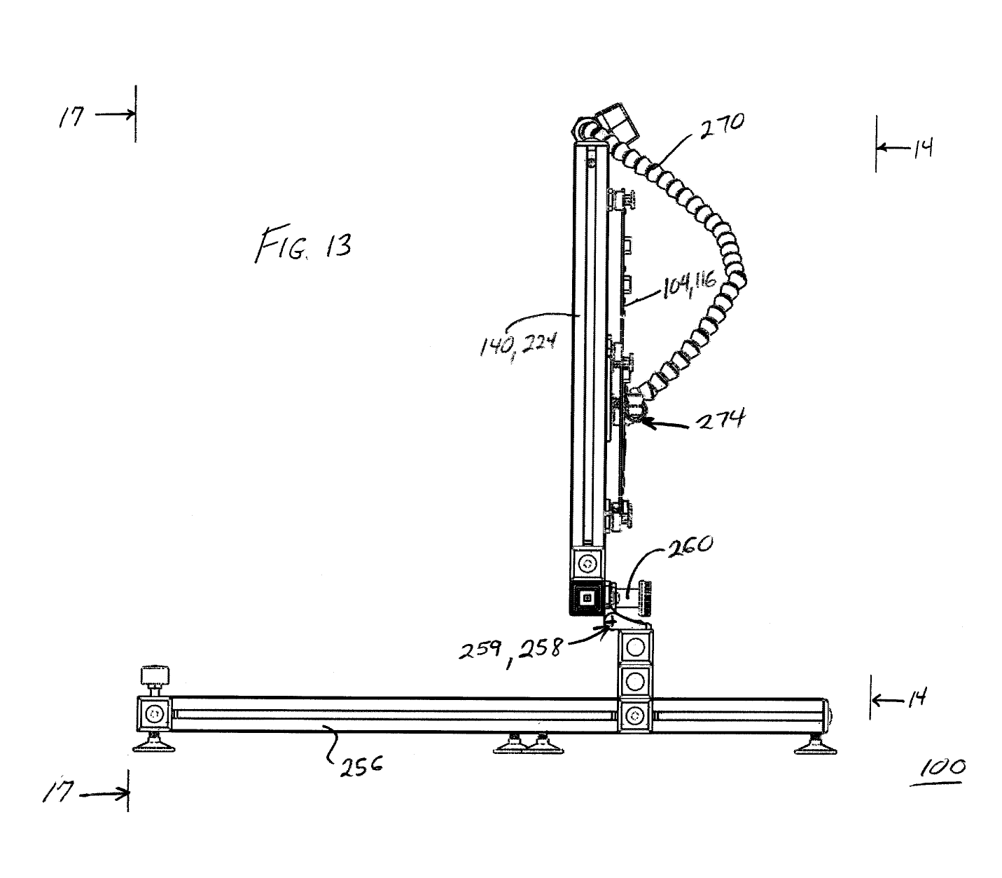

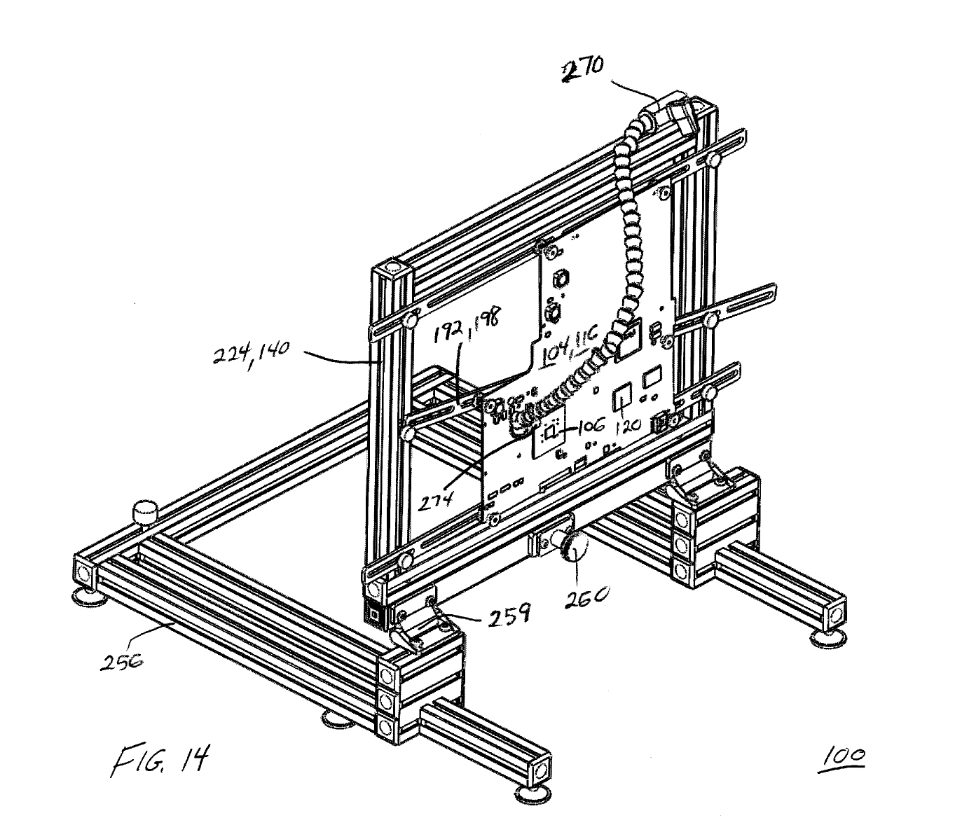

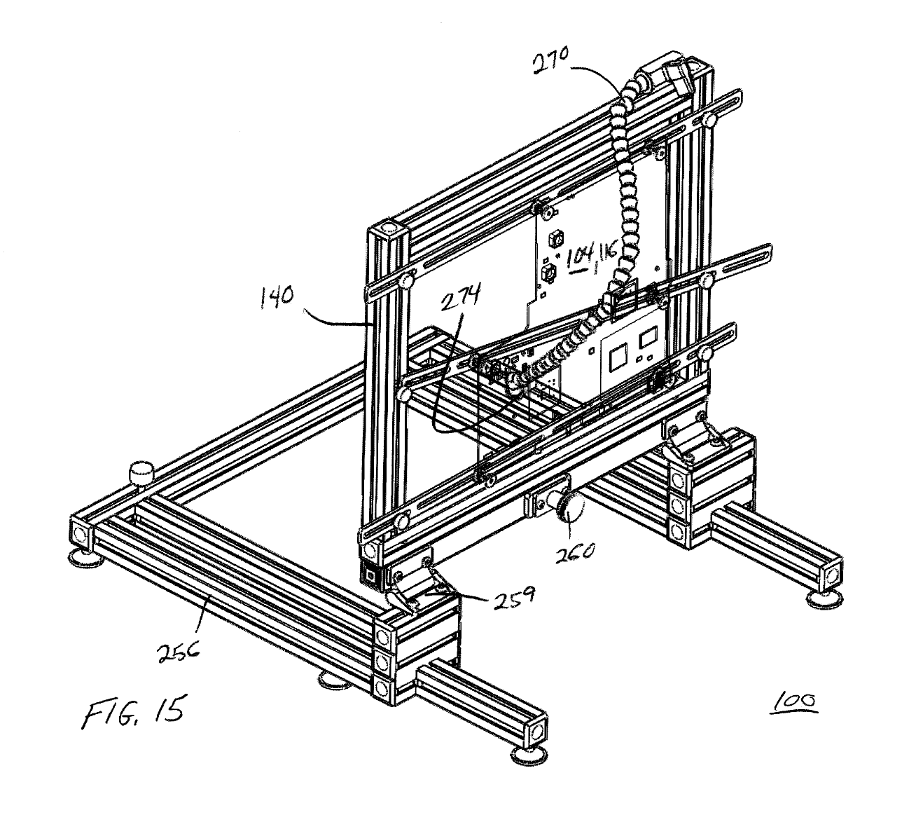

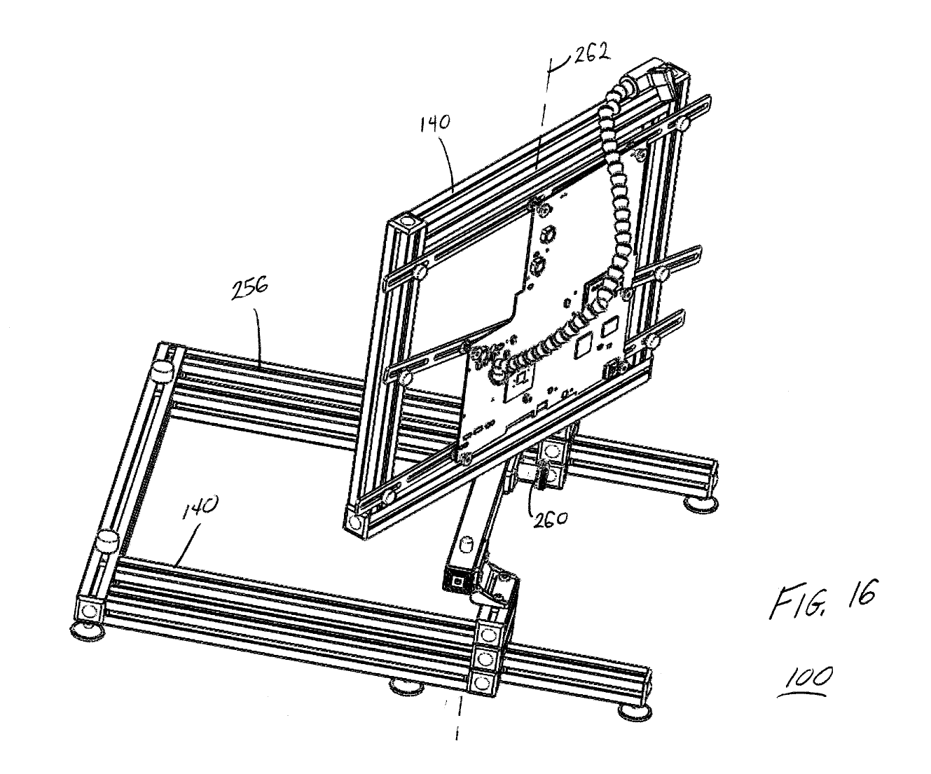

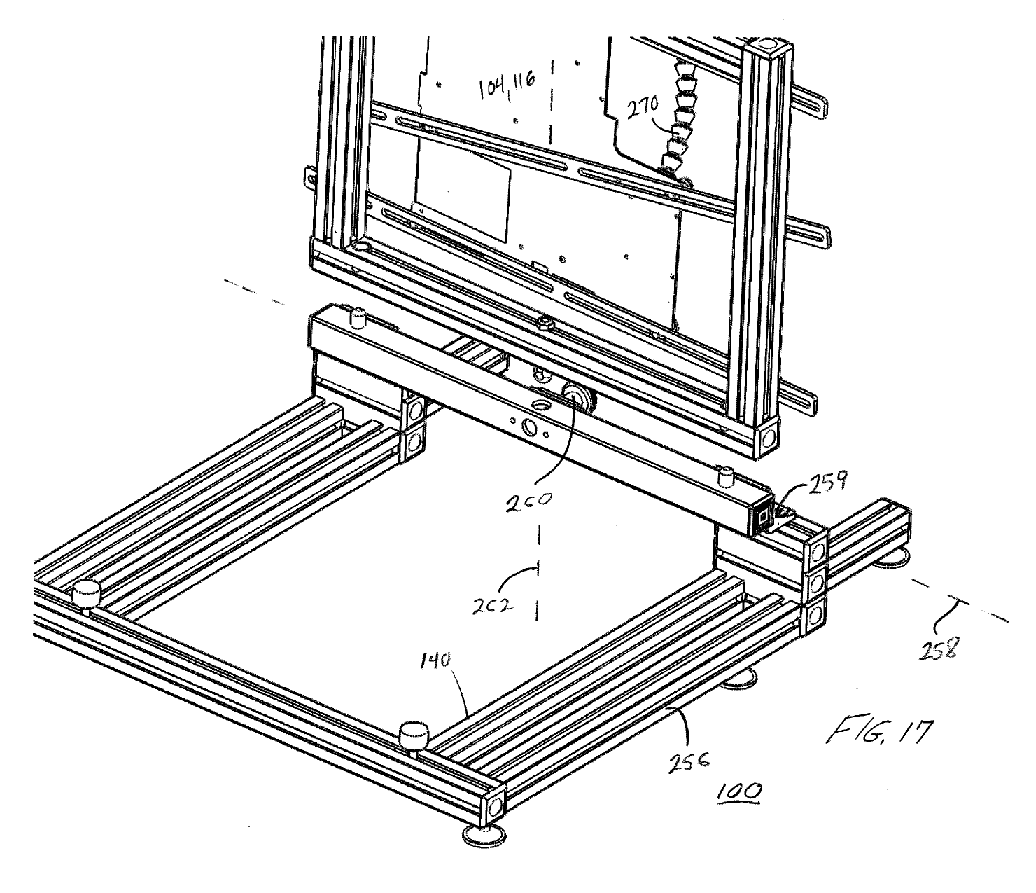

According to a specific embodiment shown in FIGS. 1, 2 and 11-13, test apparatus 100 includes a debug fixture base 256 configured to support fixture frame 140 for pivotal movement about a fixed horizontal pivot axis 258. Debug fixture base 256 includes a set of friction hinges 259 configured to permit deliberate manual pivoting movement of fixture frame 140 relative debug fixture base 256 about pivot axis 258. Friction hinges 259 are configured to retain fixture frame 140 in a desired angular orientation to provide convenient access for an operator to access electronic components 120 and circuitry on both of the opposing surfaces of primary PCB 104 until the angular orientation is manually changed by the operator. As shown in FIG. 16, debug fixture base 256 is configured to permit pivotal movement of fixture frame 140 relative thereto about a vertical pivot axis 262 to enable convenient access for an operator. Fixture frame 140 is detachable from debug fixture base 256 by manual operation of a detent mechanism 260, as best shown in FIG. 17. One of ordinary skill will understand that in an embodiment (shown in FIG. 20), test apparatus 100 includes fixture frame 140 configured to rest directly on a supporting surface, and debug fixture base 256 is omitted. Referring to FIGS. 14-15, test apparatus 100 includes air supply nozzle 274 supported by fixture frame 140 for movement in common therewith relative to pivot axis 258.

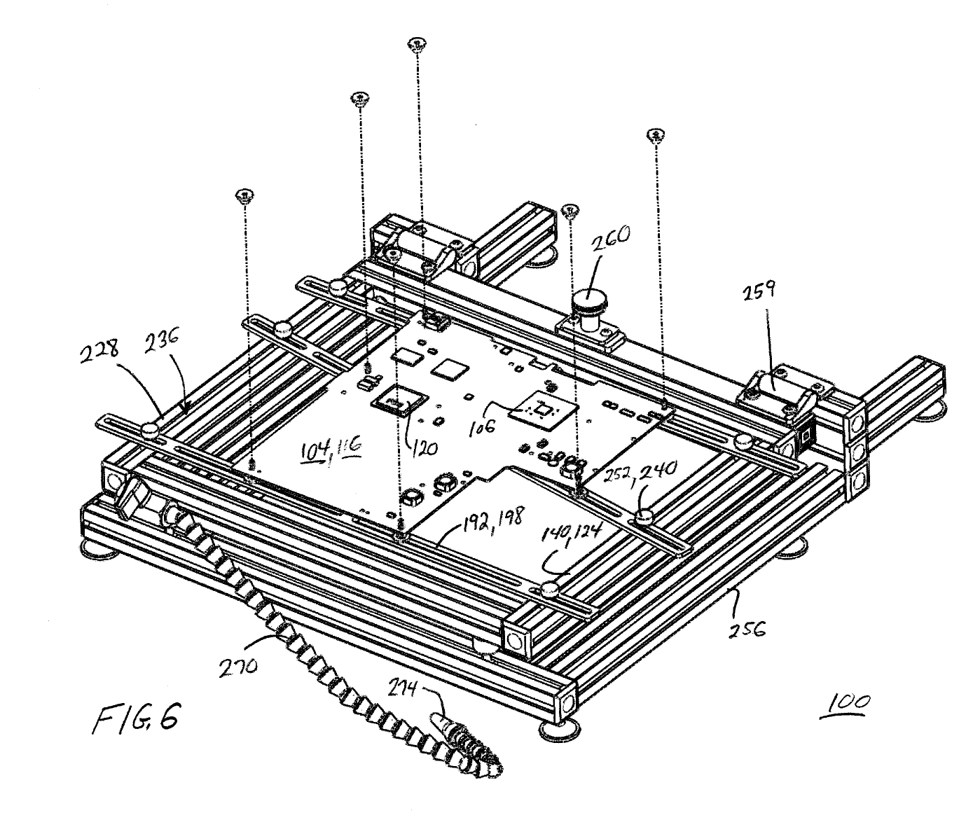

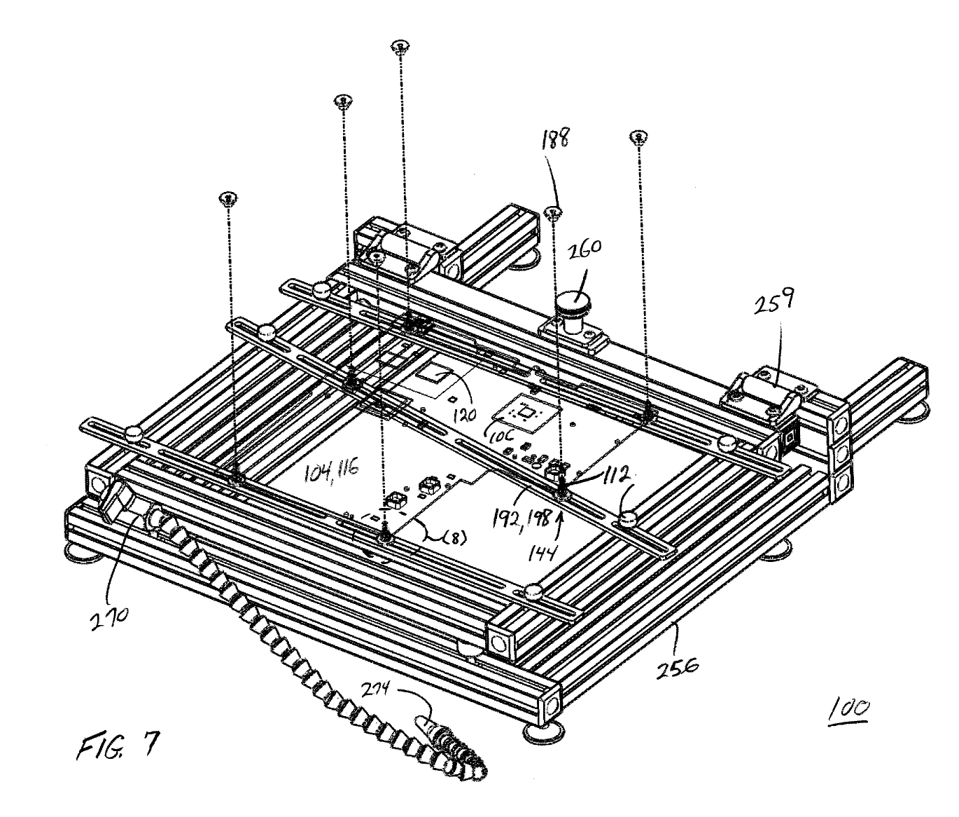

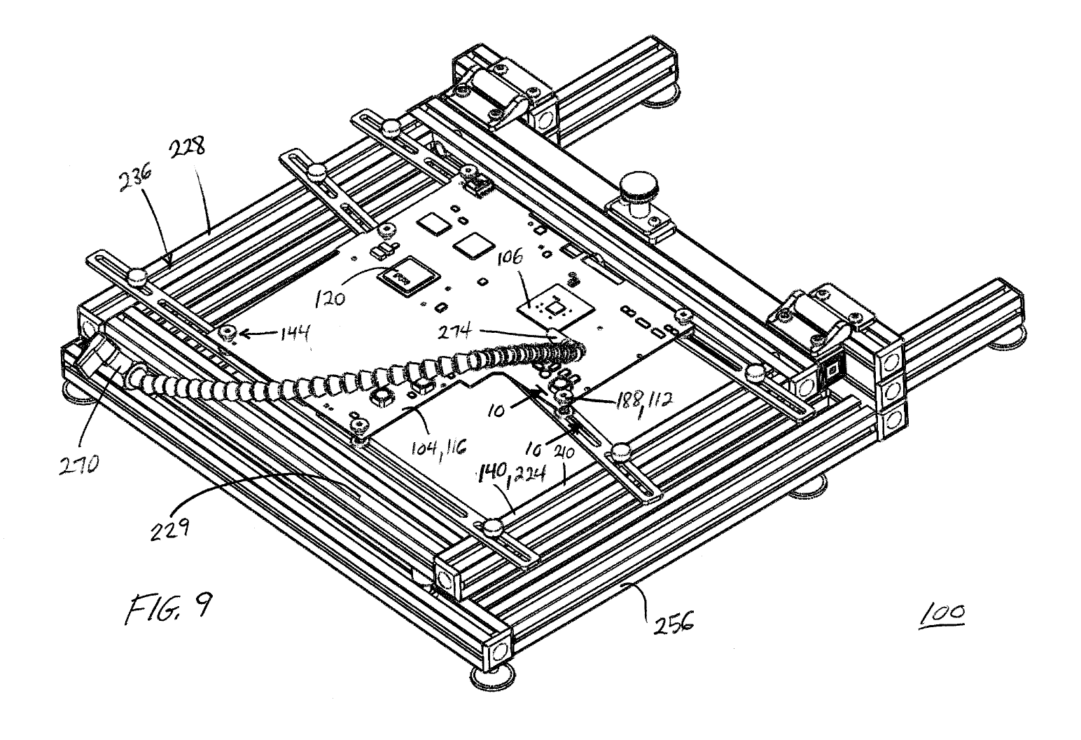

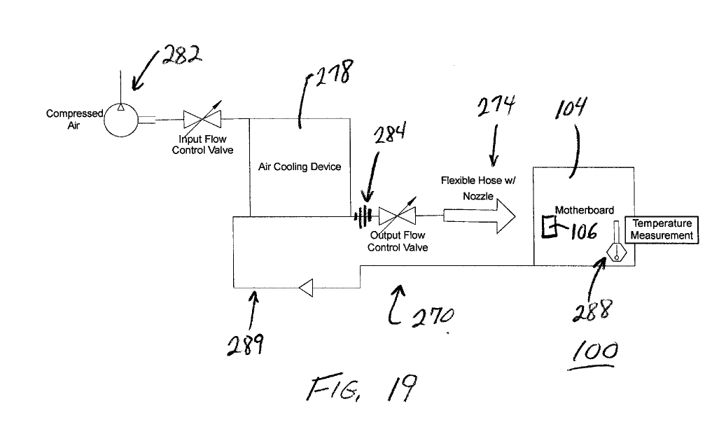

According to an embodiment illustrated in FIGS. 1, 9 and 19, test apparatus 100 comprises a cooling air supply 270 operable to supply cooling air for cooling at least a portion of the primary PCB 104 when the primary PCB 104 is supported on fixture frame 104 for testing of the same. According to an embodiment perhaps best shown in FIG. 9, test apparatus 100 comprises the cooling air supply 270 including an air supply nozzle 274 which is supported to provide cooling air for cooling at least a portion of the primary PCB 104, such as a processor 106 mounted thereupon. The air supply nozzle 274 is jointed and possesses a plurality of articulated, poseable knuckle joints, and thus is selectively positionable in any of a plurality of selected positions in relation to the primary PCB 104 when the primary PCB 104 is supported on the fixture frame 140. In the specific embodiment illustrated in FIG. 9, air supply nozzle 274 is selectively positioned to supply cooling air for cooling a processor 106 on the primary PCB 104. Comparing FIG. 9 to FIGS. 6-7, it can be observed that air supply nozzle 274 is selectively re-positionable from an inoperable position (shown in FIGS. 6-7) to locate the air supply nozzle 274 near a processor 106 (see FIG. 9) to deliver cooling lair to a selected portion of primary PCB 104, such as for cooling processor 106. According to a specific embodiment illustrated in FIG. 19, test apparatus 104 comprises the cooling air supply 270 including a vortex tube cooling apparatus 278 configured to receive primary compressed air from a primary air supply 282. The vortex tube cooling apparatus 278 is operable to produce cool air from primary compressed air supplied to the vortex tube cooling apparatus 278 from the primary air supply 282. A suitable commercially available product is a vortex tube cooling apparatus available from Exair Corporation of Cincinnati, Ohio. According to an embodiment illustrated in FIG. 19, test apparatus 100 comprises at least one air filtration device 284 connected to receive at east one of the primary compressed air and the cooling air to filter impurities from the same prior to supplying cooling air to the primary PCB 104. In the specific embodiment shown in FIG. 19, the at least one air filtration device 284 is connected to receive cooling air to filter impurities from the same. According to an embodiment illustrated in FIG. 19, test apparatus 100 comprises the primary air supply 282 including or being provided from a general supply of compressed air, the general supply of compressed air being supplied for general use in a facility where test apparatus 100 is located. According to a specific embodiment (not shown), test apparatus 100 includes cooling air supply similar to cooling air supply 270 and further including a manifold (not shown) connected downstream of the vortex tube vortex cooling apparatus 278, the manifold (not shown) being operable to provide cooling air from operation of a single vortex tube cooling apparatus 278 to multiple identical fixture frames 140 for cooling multiple primary PCB's 104 mounted on respective of the same. According to an embodiment illustrated in FIG. 19, test apparatus 100 comprises the cooling air supply 270 being operable to provide cooling air for cooling at least a portion of the primary PCB 104 when supported on fixture frame 140 (see FIG. 9) to dissipate heat and compensate for cooling effects that would be produced by a heat sink located in a native computing device (not shown). One of ordinary skill will understand that in many native computing devices (not shown), a heat sink (not shown) would be provided inside a native housing (not shown) in proximity to a processor 106 on the primary PCB 104. One of ordinary skill will understand that, in addition to use of test apparatus 100 eliminated a native computing device (not shown) and native housing (not shown) thereof during testing of primary PCB 104 on open fixture frame 140, test apparatus 100 according to an embodiment includes cooling air supply 270 that is operable to provide cooling air for cooling at least a portion of primary PCB 104 including a processor 106 to a necessary operating temperature range, and test apparatus 100 thus simplifies testing in that an operator is not required to mount a replica or native heat sink (not shown) in proximity to processor 106. According to an embodiment illustrated in FIG. 19, test apparatus 100 comprises the cooling air supply 270 including a suitable temperature sensing device 288 operably connected for communication via a control loop 289 to cause cooling air supply 270 to provide more or less cooling air through air supply nozzle 274 as may be determined to be necessary, by measurement of temperature by temperature sensing device 288 and by comparison of one or more temperature values to a necessary operating temperature range, or determined by any suitable method, simplification, estimation, or general practice, for cooling processor 106 to a necessary operating temperature range.

According to an embodiment illustrated in FIG. 1 and as best shown in FIG. 20, test apparatus 100 comprises a plurality of mating connector members 320 configured to be connected to corresponding of the plurality of on-board interconnects 124 to establish connections across a plurality of corresponding wired connections 324 to respective of a plurality of off-board peripherals 328 when the primary PCB 112 is supported on the fixture frame 140. According to an embodiment illustrated in FIG. 1 and FIG. 20, test apparatus 100 comprises the plurality of wired connections 324 connected to respective of a plurality of off-board peripherals 328 from the primary PCB 104 and mimicking architecture of a native computing device when the primary PCB 104 is supported on the fixture frame 140.

According to an embodiment illustrated in FIG. 1 and best shown in FIG. 20, test apparatus 100 comprises a plurality of off-board peripherals 328 including an off-board power supply 336. It will be understood that, in FIG. 20, debug fixture base 256 is omitted for clarity, and fixture frame 140 is supported on a suitable horizontal support surface. According to an embodiment illustrated in FIG. 20, test apparatus 100 comprises off-board power supply 336 which includes a replica battery 338. In the specific embodiment shown in FIG. 20, replica battery 338 is compatible with a native computing device (not shown) and is substantially identical to a native battery (not shown) of the native computing device (not shown). One of ordinary skill will understand that any suitable replica battery 338 can be used. One of ordinary skill will understand that, where a native computing device (not shown) lacks a native battery (not shown) and includes a native power supply cord (not shown) for use with a standard electrical wall socket (not shown), or similar connection to a permanent, non-battery source of electric power (not shown), test apparatus 100 can include a replica of the native power supply cord (not shown) and any related circuitry.

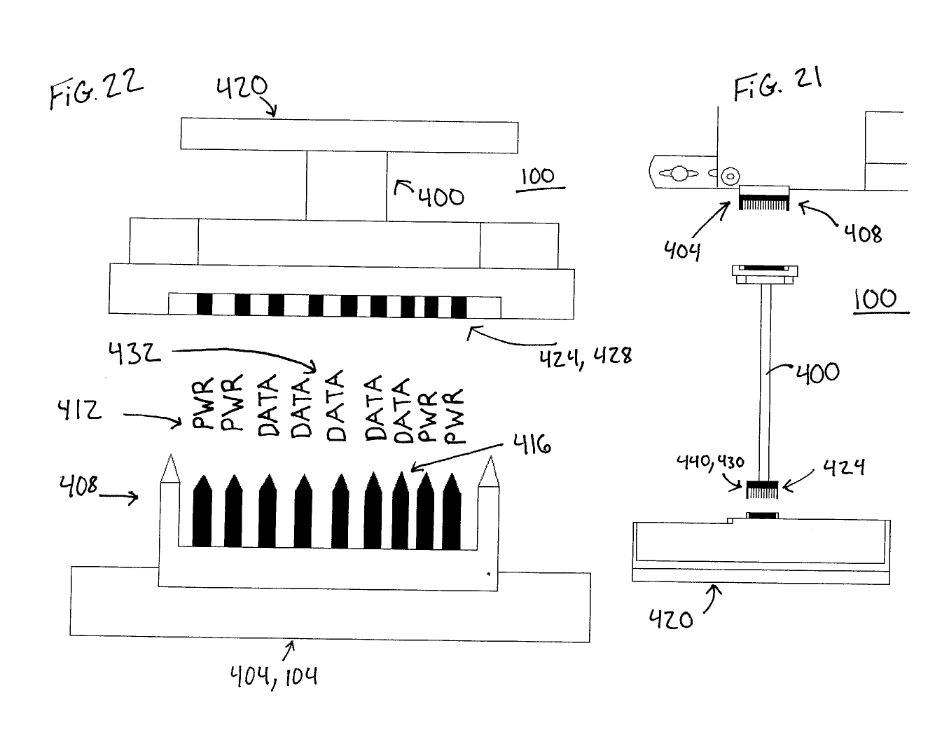

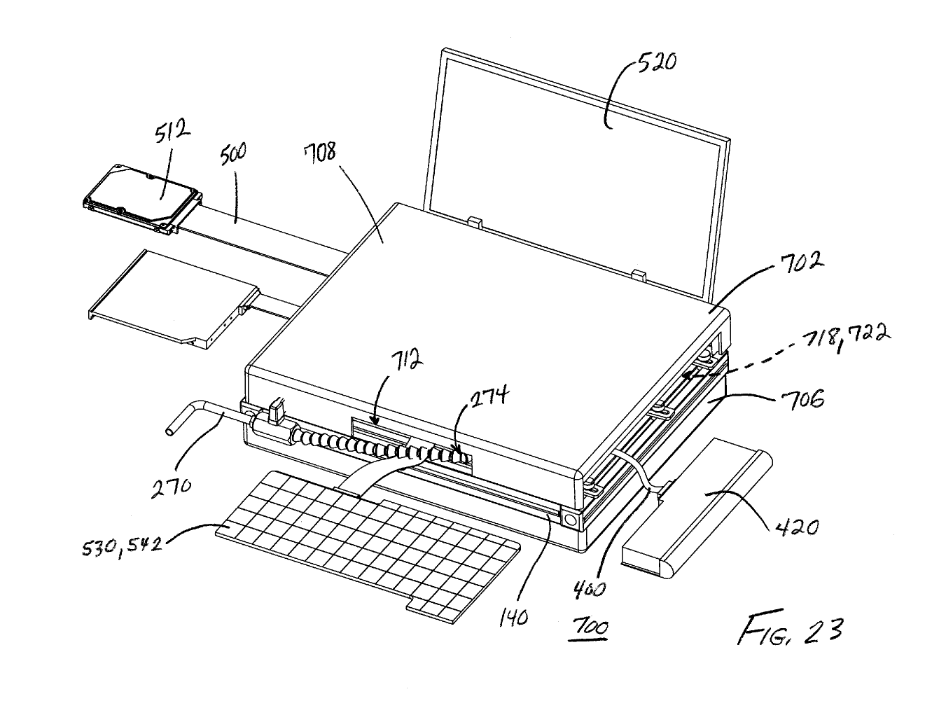

According to an embodiment illustrated in FIG. 20, and as best shown in FIG. 21, test apparatus 100 comprises a battery connector extension cable 400. Primary PCB 104 comprises a certain one among the plurality of the on-board interconnects 124 that is an on-board battery port 404. As shown in FIG. 22, battery port 404 includes a certain pinout configuration 408 that includes both power supply contacts 412 and data communication contacts 416. Test apparatus 100 includes a replica battery 420 suitable for providing power to primary PCB 104 via a suitable connection to battery port 404. One of ordinary skill will understand that primary PCB 104 having on-board battery port 404 is not configured to support a native battery (not shown) or a replica battery 420 that is substantially identical to a native battery (not shown). One of ordinary skill will understand that, during normal use of a native computing device (not shown), a native housing (not shown) is configured to support a native battery (not shown) in an installed position (not shown) in which mating power contacts and mating data contacts of the native battery (not shown) are positioned for mating engagement with the battery port 404 having the certain pinout configuration 408. One of ordinary skill will understand that a replica battery 420 is supported in spaced relation to primary PCB 104 when primary PCB 104 is supported on fixture frame 140 for testing of the same. Test apparatus 100 comprises a battery connector extension cable 400 connected between on-board battery port 404 and replica battery 420 for providing power to primary PCB 104. Referring to FIG. 21, battery connector extension cable 400 includes a replica mating battery connection 424 configured for mating engagement with battery port 404 and having replica mating power contacts 428 and replica mating data contacts 432 arranged in the same configuration as respective native mating power contacts (not shown) and native mating data contacts (not shown) of a native battery (not shown). Replica mating battery connection 424 thus has a replica mating connector configuration arranged for mating engagement with the certain pinout configuration 408 of battery port 404 and configured for mating engagement with both power supply contacts 412 and data communication contacts 416. Referring to FIG. 22, battery connector extension cable 400 at an opposite end thereof includes a replica battery port 436 having a replica pinout configuration 440 that is substantially identical to on-board battery port 404 having certain original pinout configuration 408. Battery connector extension cable 400 at replica battery port 436 is configured to be connected to replica battery 420. One of ordinary skill will understand that structure other than power supply contacts 412 and data communication contacts 416 configured to establish suitable power and data connections to replica battery 420 can be omitted to reflect that replica battery 420 is not supported by a native housing (not shown). Likewise, one of ordinary skill will understand that, according to an embodiment (not shown), replica battery port 436 can be permanently hardwired with replica battery 420. Referring to FIG. 21, battery connector extension cable 400 is configured to meet necessary specifications for conveying power from the replica battery 420 to the primary PCB 104, and is configured to meet necessary specifications for communicating data between the replica battery 420 and primary PCB 104 to enable proper operation of the replica battery 420 to substantially mimic a native battery (not shown) for testing the primary PCB 104 on test apparatus 100. It will be understood that test apparatus 100 includes a plurality of different battery connector extension cables 400, each configured differently for connecting a specific replica battery port 436 to a corresponding replica battery 420 for providing power to different primary PCB's 104, because the preceding replica battery port 436 and replica battery 420 vary among a plurality of different native computing devices (not shown) and for use in connection with different primary PCB's 104.

According to an embodiment illustrated in FIGS. 1 and 20, test apparatus 100 comprises a plurality of peripheral interconnect extension cables 500. Each peripheral interconnect extension cable 500 includes a replica native mating peripheral pinout connector 504 suitable for connecting in mating relationship with a corresponding on-board interconnect peripheral pinout 124. Each peripheral interconnect extension cable 500 includes a remote replica peripheral pinout connector 508 identical to the corresponding on-board interconnect 124 for connecting in mating relationship with a corresponding replica peripheral 512. Each peripheral interconnect extension cable 500 extends between on-board interconnect peripheral pinout 124 and off-board replica peripheral 512 for connecting the same.

According to a specific embodiment shown in FIG. 20, test apparatus 100 includes one of the replica peripherals 512 being an off-board replica display 520. A display interconnect extension cable 528 connects the replica display 520 with a corresponding display interconnect 528. Display interconnect extension cable 528 includes a replica display mating connector 532 configured for mating engagement with display interconnect 528. Replica display 520 is supported for viewing by an operator (not shown). In a specific embodiment shown in FIG. 20, replica display 520 is supported by fixture frame 140 adjacent to primary PCB 104 for temporary connection thereto during testing of primary PCB 104.

According to an embodiment illustrated in FIG. 20, test apparatus 100 includes an off-board replica operator data input device 530 supported in proximity to the fixture frame 140 for temporary connection to the primary PCB 104 during testing. The plurality of on-board interconnects 124 includes an operator data input device interconnect 534 configured to be connected to the off-board operator data input device 530. Test apparatus 100 includes an operator connector extension cable 538. Operator extension cable 538 at opposite ends thereof is configured to be connected between operator data input device interconnect 534 and operator data input device 530. Although other suitable operator data input devices 530 can be used, in a specific embodiment illustrated in FIG. 20, operator data input device 530 is a replica keyboard 542. One of ordinary skill will understand that, according to embodiments, test apparatus 100 can comprise an off-board operator input device 530 including at least one of the following: a set of input keys, a key emulator, a keyboard, and a keyboard emulator.

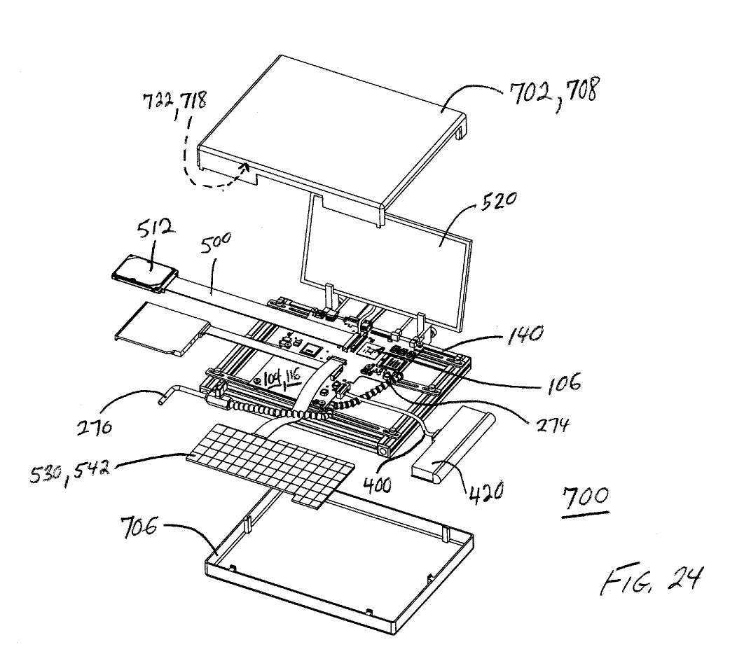

Illustrated in FIG. 23-24 is test apparatus 700 according to an alternative embodiment. Test apparatus 700 is substantially identical to test apparatus 600, except as otherwise described in this paragraph and illustrated in the drawings. Test apparatus 700 includes a universal test fixture enclosure 702. Universal test fixture enclosure 702 includes a lower peripheral enclosure 706 defining a continuous lower peripheral wall having a rectangular footprint and dimensioned to extend beneath fixture frame 140. Lower peripheral enclosure 706 is configured to rest upon a supporting surface 710 and serve as a base or pedestal supporting fixture frame 140 above the supporting surface 710. Universal test fixture enclosure 702 includes an upper enclosure 708 configured for cooperation with fixture frame 140 and having a top which is spaced above fixture frame 140 and above primary PCB 104. Universal test fixture enclosure 702 has an opening 712 dimensioned and positioned to permit cooling air supply nozzle 274 to extend into proximity of primary PCB 104 located therein to deliver cooling air in the area of a processor 106. It will be understood that universal test fixture enclosure 702 cooperates with fixture frame 104 and cooling air supply 270 to enable an operator to perform testing with primary PCB 104 operating in a prescribed, necessary temperature range associated with the native computing device (not shown). Test apparatus 700 thus includes universal test fixture enclosure 702 dimensioned to cooperate with the fixture frame 140 to at least partially enclose a substantially enclosed zone 718 (see FIG. 24) about the primary PCB 104. The substantially enclosed zone 718 thus defines a temperature controlled zone 722 about the primary PCB 104 and corresponding to the substantially enclosed zone 718.

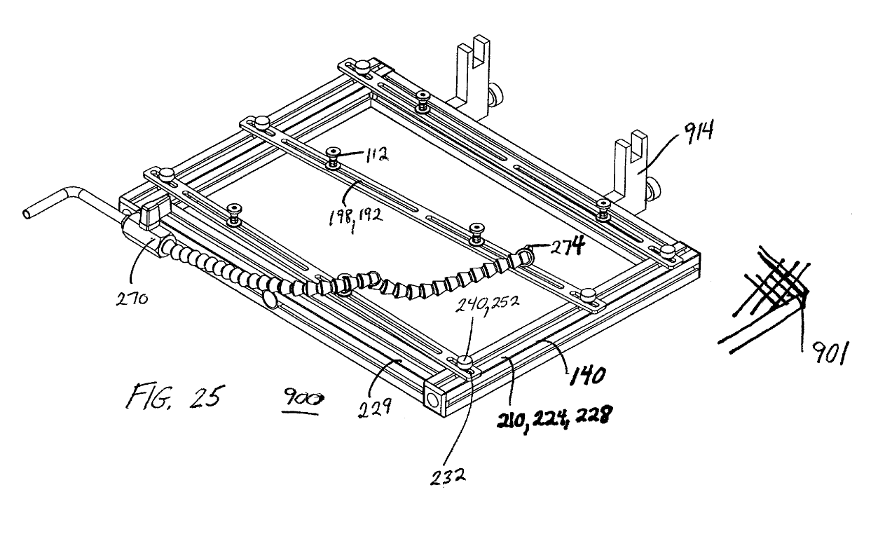

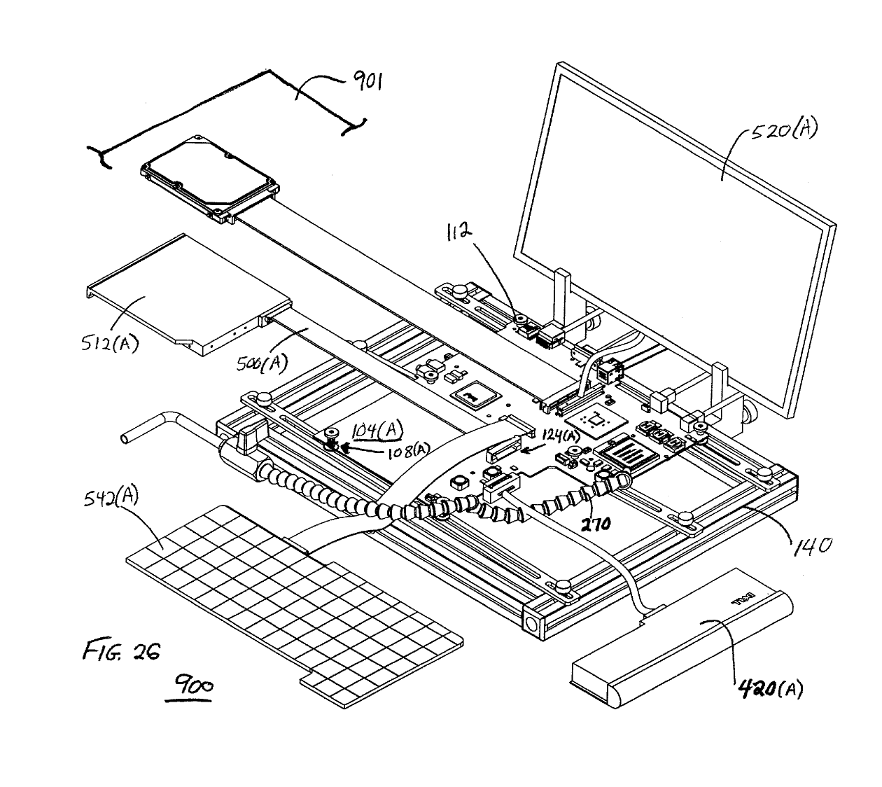

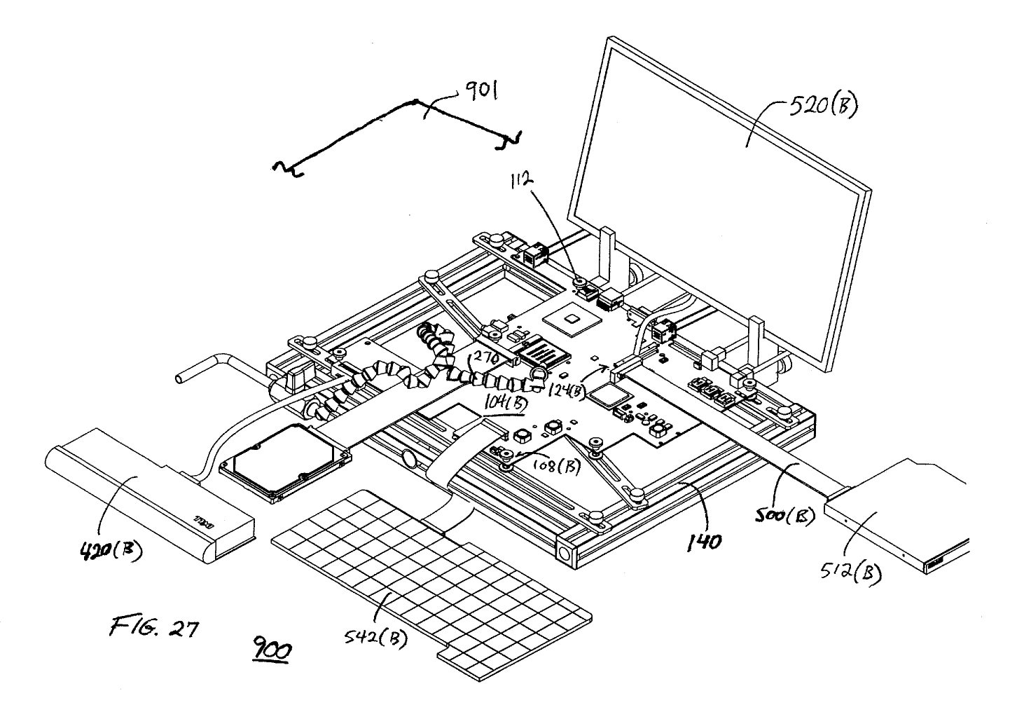

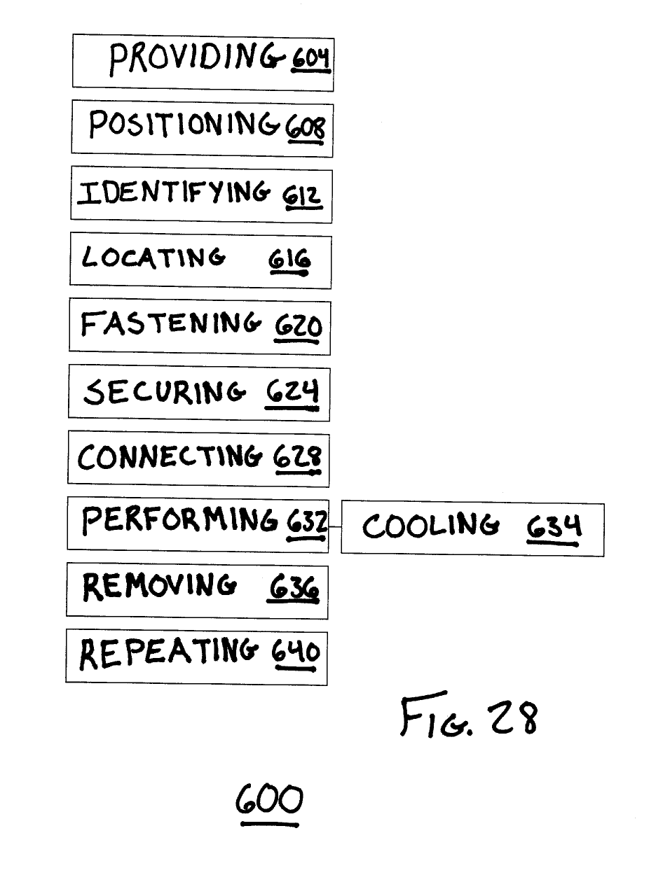

Illustrated in FIGS. 25-27 is test apparatus 900 according to an embodiment. Test apparatus 900 is identical to test apparatus 100, except as otherwise described in this paragraph or shown in the drawings. Test apparatus 900 differs from test apparatus 100 (shown in FIG. 1) in that test apparatus 900 lacks a debug fixture base 256. Test apparatus 900 includes fixture frame 140 supported on a suitable support 901, such as a horizontal support surface illustrated in FIGS. 25-27. It will be understood that fixture frame 140 can be supported in any desired orientation. Test apparatus 900 is configured for testing a series of disparate primary PCB's 104 each having differently arranged mounting holes 108. More particularly, test apparatus 900 in FIG. 26 is shown with fixture frame 140 thereof having mounted thereon an exemplary first certain primary PCB 104(A), and test apparatus 900 including a plurality of corresponding first certain replica peripherals 512(A), and a plurality of corresponding first certain replica wired connections 500(A). It will be understood that, as shown in FIG. 26, the first certain primary PCB 104(A) includes a plurality of corresponding first certain on-board interconnects 124(A), and corresponding of the first certain replica wired connections 500(A) are connected between the first certain on-board interconnects 124(A) and respective of the first certain replica peripherals 512(A). It can be observed, in FIG. 26, that first certain primary PCB 104(A) includes a corresponding plurality of first certain mounting holes 108(A) at corresponding first certain mounting hole locations. It can be observed by reference to FIG. 26 that test apparatus 900 includes a plurality of fixture mounting posts 112 supported by fixture frame 140 and selectively, releasably positioned at respective first certain mounting post locations 144 corresponding to at least three of the first certain mounting holes 108(A), and further that the fixture mounting posts 112 are received in respective of the first certain mounting holes 108(A) for temporarily mounting the first certain primary PCB 104(A) on fixture frame 140 for testing of the same. Referring to FIG. 27, test apparatus 900 is shown therein with fixture frame 140 thereof having mounted thereon an exemplary second certain primary PCB 104(B), and test apparatus 900 including a plurality of corresponding second certain replica peripherals 512(B), and a plurality of corresponding second certain replica wired connections 500(B). It will be understood that, as shown in FIG. 27, the second certain primary PCB 104(B) includes a plurality of corresponding second certain on-board interconnects 124(B), and corresponding of the second certain replica wired connections 500(B) are connected between the second certain on-board interconnects 124(B) and respective of the second certain replica peripherals 512(B). It can be observed, in FIG. 27, that second certain primary PCB 104(B) includes a corresponding plurality of second certain mounting holes 108(B) at corresponding second certain mounting hole locations. It can be observed by reference to FIG. 27 that test apparatus 900 includes a plurality of fixture mounting posts 112 supported by fixture frame 140 and selectively, releasably positioned at respective second certain mounting post locations 144 corresponding to at east three of the second certain mounting holes 108(B), and further that the fixture mounting posts 112 are received in respective of the second certain mounting holes 108(B) for temporarily mounting the second certain primary PCB 104(B) on fixture frame 140 for testing of the same. It can be observed that the exemplary first certain primary PCB 104(A) and second certain primary PCB 104(B) are of different size and shape and have differently located mounting holes (108(A) and 108(B)). It can be observed, by comparing FIG. 26 and FIG. 27, that the fixture mounting posts 112 are moved and positioned in different locations on fixture frame 140 to be received in at least three of the plurality of differently located mounting holes (108(A) and 108(B)) corresponding to first certain primary PCB 104(A) and second certain primary PCB 104(B). It can also be observed that, as shown in FIG. 26, first certain primary PCB 104(A) includes a plurality of on-board first certain interconnects 124(A) different from the plurality of on-board second certain interconnects 124(B) shown in FIG. 27 and located on the second certain primary PCB 104(A) illustrated therein. It will be understood, by comparison of FIG. 26 and FIG. 27, that test apparatus 900 includes at east the following: fixture frame 140 supporting selectively positionable fixture mounting posts 112, and an inventory of interchangeable first certain and second certain replica peripherals (512(A) and 512(B)) and an inventory of interchangeable first certain and second certain replica wired connections (500(A) and 500(B)), where the preceding inventories correspond to native peripherals (not shown) and native wired connections (not shown) of native computing devices (not shown) associated with an identified inventory of first certain and second certain primary PCB's (104(A) and 104(B)) to be tested. It will be observed, in FIG. 26 and FIG. 27, that test apparatus 900 includes among replica peripherals 512: a replica display 520, replica battery 338, replica keyboard 542 and respective replica wired connections 500 for the same. As shown in FIGS. 25 and 26, test apparatus 900 includes a pair of display brackets 914 mounted on fixture frame 140 and configured to support a replica display 520 for viewing by an operator (not shown). It will be understood that test apparatus 900 including fixture frame 140 can include a universal test fixture enclosure 702 as shown in FIGS. 23-24, and cooling air supply 270 including cooling air supply nozzle 240.

Illustrated in FIG. 28 is a method 600 (“test method 600)” for testing in series a plurality of disparate primary PCB's. Each primary PCB is substantially identical to above-described primary PCB 104. It will be understood that the series of different primary PCB's originates in disparate native computing devices (not shown). Each primary PCB has a plurality of mounting holes arranged in spaced relation in a board plane. Mounting holes in different primary PCB's are located at different mounting hole locations. Test method 600 includes steps following below.

Test method 600 includes the step of: providing 604 test apparatus for testing a primary PCB, the test apparatus including a plurality of fixture mounting posts supported by a fixture frame, and the fixture mounting posts being selectively positionable in a mounting plane relative to the fixture frame. It will be understood that test apparatus is substantially identical to test apparatus 100 elsewhere described herein.

Test method 600 includes the step of: positioning 608 a primary PCB adjacent to the fixture frame with the board plane in substantially parallel relation to the mounting plane, the primary PCB being free of the primary housing. It will be understood that primary PCB is substantially identical to primary PCB 104 elsewhere described herein.

Test method 600 includes the step of: identifying 612 among mounting hole locations on the primary PCB at least three identified mounting hole locations.

Test method 600 includes the step of: locating 616 on the fixture frame a plurality of fixture mounting post locations aligned with the at least three identified mounting hole locations.

Test method 600 includes the step of: fastening 620 a plurality of fixture mounting posts in the mounting plane at respective of the at least three identified mounting hole locations by manually placing a base of each fixture mounting post in a releasably fastened relationship with the fixture frame at each of the at least three identified mounting hole locations.

Test method 600 includes the step of: securing 624 in each of the at least three identified mounting hole locations a distal end of a respective fixture mounting post.

Test method 600 includes the step of: connecting 628 to a plurality of on-board interconnects a corresponding plurality of off-board peripherals connected thereto by respective wired connections, the plurality of off-board peripherals including an off-board power supply, the plurality of off-board peripherals including an off-board display, the plurality of off-board peripherals including a user data input device.

Test method 600 includes the step of: performing 632 test procedures on the primary PCB.

Test method 600 includes the step of: removing 636 from the test apparatus the primary PCB.

Test method 600 includes the step of: repeating 640 for each primary PCB the steps of providing 604, positioning 608, identifying 612, locating 616, fastening 620, securing 624, connecting 628, performing 632 and removing 636.

Test method 600 includes the following optional step: cooling 634 at least a portion of the primary PCB when performing test procedures by providing cooling air from a cooling air supply to the primary PCB for cooling at least a portion of the primary PCB. It will be understood that a suitable cooling air supply can be identical to cooling air supply 270 elsewhere described herein.

It can be necessary, from time to time, to test a primary PCB 104 of a native computing device (not shown) to diagnose and correct performance problems of primary PCB 104, electronic components 120 located on the primary PCB 104, off-board peripherals, and systems of the native computing device (not shown) and primary PCB 104. Test apparatus 100 includes a fixture frame 140 and plurality of fixture mounting posts 112 positionable in different locations is configured and configurable to support and test a series or plurality of disparate primary PCB's 104 each having mounting holes in different locations. Test apparatus 100 including fixture frame 140 and plurality of fixture mounting posts 112 positionable in different locations thus provides a universal test apparatus configured for supporting and testing a plurality of disparate primary PCB's 104 originating in corresponding, different, native computing devices (not shown). Test apparatus 100 thus eliminates the need for multiple hot test fixtures each dedicated to a corresponding, single primary PCB for testing the same. Test apparatus 100 also eliminates the space and organizational burden necessary to store multiple hot test fixtures. Test apparatus 100 eliminates the expense and time necessary to maintain multiple hot test fixtures each corresponding to a single primary PCB. Method 600 provides benefits similar to those described for test apparatus 100. Apparatus of varying scope for testing PCB's are described. Methods of varying scope for testing PCB's are described. Apparatus of varying scope for testing primary PCB's are described. Methods of varying scope for testing primary PCB's are described. Although specific embodiments are illustrated and described herein, it will be appreciated by those of ordinary skill in the art that any arrangement which is calculated to achieve the same purpose may be substituted for the specific embodiments shown. This application is intended to cover any adaptations or variations. One of skill in the art will readily appreciate that the names of the methods and apparatus are not intended to limit embodiments. Furthermore, additional methods and apparatus can be added to the components, functions can be rearranged among the components, and new components to correspond to future enhancements and physical devices used in embodiments can be introduced without departing from the scope of embodiments. One of skill in the art will readily recognize that embodiments are applicable to future apparatus and methods. Terminology used in this application is intended to encompass environments and alternate technologies which provide the same functionality as described herein.

What is claimed is:

1. Apparatus for testing a primary PCB of a native computing device, the native computing device having a primary housing configured to support therein the primary PCB during normal use of the native computing device, the primary housing including a spaced plurality of mounts arranged to engage the primary PCB to support the same relative to the primary housing, the primary PCB having a plurality of spaced mounting holes arranged in substantially planar spaced relation for receiving the plurality of mounts, the primary PCB having a plurality of interconnects each configured for wired connection to a corresponding off-board peripheral, the primary PCB being removable from the primary housing for testing the primary PCB, said apparatus comprising:
a plurality of fixture mounting posts selectively positionable in alignment with the plurality of mounting holes for the fixture mounting posts to be received in the mounting holes to support the primary PCB on the apparatus; and
a fixture frame configured to support the plurality of fixture mounting posts in a plurality of selected mounting post locations, each selected mounting post location being selectable by an operator for selectively locating the plurality of fixture mounting posts on the fixture frame in alignment with the plurality of mounting holes when the primary PCB is positioned adjacent to the fixture frame with the fixture mounting posts interposed there between.

2. Apparatus according to claim 1, and further comprising:
each fixture mounting post having a distal end spaced apart from the fixture frame, the distal end being configured to be received in a respective mounting hole aligned therewith, each fixture mounting post having a base spaced from the distal end, the base being configured for substantially fixed engagement with the fixture frame in a selected mounting post location, each fixture mounting post configured to be manually positioned on the fixture frame in a selected mounting post location by bringing the base into substantially fixed engagement with the fixture frame at a selected mounting post location.

3. Apparatus according to claim 1, and further comprising:
each fixture mounting post being configured to be retained in substantially fixed engagement with the fixture frame at a corresponding selected mounting post location, each fixture mounting post being manually removable from substantially fixed engagement with the fixture frame by an operator for relocating the same to a different selected mounting post location.

4. Apparatus according to claim 3, and further comprising:
each fixture mounting post being configured to be attracted against the fixture frame by magnetic forces to facilitate substantially fixed engagement there between.

5. Apparatus according to claim 4, and further comprising:
each fixture mounting post having a base configured for substantially fixed engagement with the fixture frame, the base being configured to be attracted against the fixture frame by magnetic forces to facilitate substantially fixed engagement there between.

6. Apparatus according to claim 5, and further comprising:
each fixture mounting post having a base comprising magnetic material, the fixture frame comprising ferromagnetic material.

7. Apparatus according to claim 6, and further comprising:
each fixture mounting post at the distal end being formed of nonmagnetic material, each fixture mounting post being configured for supporting the primary PCB apart from the base with only nonmagnetic material located adjacent the primary PCB to substantially avoid exposing the primary PCB to magnetic forces drawing the base against the fixture frame.

8. Apparatus according to claim 7, and further comprising:
each fixture mounting post including an inner barrier material positioned between the base and distal end to substantially prevent electrical communication from the primary PCB to the base, the inner barrier material being substantially nonconductive of electricity.

9. Apparatus according to claim 8, and further comprising:
each fixture mounting post including an inner barrier material positioned between the base and distal end to substantially prevent communication of magnetic forces from the base to the primary PCB, the inner barrier material being substantially nonmagnetic.

10. Apparatus according to claim 7, and further comprising:
each fixture mounting post including an inner barrier material positioned between the base and distal end, the inner barrier material being substantially nonmagnetic to substantially prevent communication of magnetic forces from the base to the primary PCB.

11. Apparatus according to claim 10, and further comprising:
each fixture mounting post including an outer barrier material positioned between the base and distal end, the outer barrier material being substantially nonmagnetic to substantially prevent communication of magnetic forces from the distal end to the primary PCB.

12. Apparatus according to claim 11, and further comprising:
the distal end being formed of non-ferrous alloy material.

13. Apparatus according to claim 12, and further comprising:
each fixture mounting post from the base to the distal end being formed of non-ferrous alloy material.

14. Apparatus according to claim 13, and further comprising:
each fixture mounting post including a distal retaining member removably installed at the distal end to prevent inadvertent dislocation of the primary PCB from the fixture mounting post, the distal retaining member being formed of nonmagnetic material.

15. Apparatus according to claim 14, and further comprising:
the distal retaining member being formed of non-ferrous alloy material.

16. Apparatus according to claim 1, and further comprising:
the fixture frame including a plurality of first locating members configured to support the plurality of fixture mounting posts, each of the first locating members providing for a respective fixture mounting post one degree of freedom for the same to be selectively positioned along a mounting location first axis, each first locating member being configured for an operator to selectively locate a respective fixture mounting post thereupon at a selected location on the mounting location first axis, the selected location on the mounting location first axis corresponding to a respective selected mounting hole location, the selected location on the mounting location first axis being in alignment with a corresponding one of the plurality of mounting holes when the primary PCB is positioned adjacent to the fixture frame with the fixture mounting posts interposed there between.

17. Apparatus according to claim 16, and further comprising:
each first locating member including an elongated first rail member supported to extend substantially along the mounting location first axis, the first rail member being configured to support a corresponding fixture mounting post at any of a plurality of selected locations along the mounting location first axis.

18. Apparatus according to claim 16, and further comprising:
each elongated first rail member including a respective elongated, open first alignment channel defined in the first rail member, the first alignment channel extending substantially along the first axis, each fixture mounting post having an alignment portion, the alignment portion being configured to be received in the first aligning channel for aligning the fixture mounting post on the first rail member at any of a plurality of selected locations along the first axis.

19. Apparatus according to claim 1, and further comprising:
the fixture frame including a second locating member configured to support the plurality of first locating members, the second locating member providing for each of the plurality of a first locating members one degree of freedom for the same to be selectively positioned along a mounting location second axis, the second locating member being configured for an operator to selectively locate each first locating member thereupon at a corresponding selected location on the mounting location second axis, each corresponding selected location on the mounting location second axis corresponding to a respective mounting hole location, each selected location on the mounting location second axis being in alignment with a location on the mounting location second axis with a corresponding one of the plurality of mounting holes when the primary PCB is positioned adjacent to the fixture frame with the fixture mounting posts interposed there between.

20. Apparatus according to claim 19, and further comprising:
each second locating member including an elongated second rail member supported to extend substantially along the mounting location second axis, the second rail member being configured to support a plurality of first locating members at any of a plurality of selected locations along the mounting location second axis, each first locating member having a corresponding fixture mounting post supported thereon.

21. Apparatus according to claim 20, and further comprising:
each elongated second rail member including a respective elongated, open second locating channel defined in the second rail member, the second locating channel extending substantially along the mounting location second axis, the second rail member being configured to support a corresponding first locating member positioned in the second locating channel at any of a plurality of selected locations along the mounting location second axis, the second locating channel receiving a plurality of secondary releasable fastening devices, the plurality of secondary releasable fastening devices being selectively movable along the secondary locating channel in common with corresponding of the first locating members, each of the secondary releasable fastening devices being manually releasably engageable for releasably fastening a corresponding first locating member in a selected location along the mounting location second axis.

22. Apparatus according to claim 19, and further comprising:
the fixture frame including a plurality of pairs of identical second locating members extending in spaced, parallel relation to support the plurality of first locating members at opposite ends thereof.

23. Apparatus according to claim 19, and further comprising:
the mounting location second axis extending in substantially perpendicular relationship to the mounting location first axis, cooperation of the mounting location second axis with the mounting location first axis defining a fixture mounting plane, the primary PCB having a primary board plane defined by the plurality of mounting holes, the fixture mounting plane extending in substantially parallel relationship with the primary board plane when the primary PCB is positioned adjacent to the fixture frame with the fixture mounting posts interposed there between.

24. Apparatus according to claim 19, and further comprising:
a plurality of secondary releasable fastening devices each releasably engageable for selectively positioning a respective first locating member on the second locating member at a selected location on the mounting location second axis.

25. Apparatus according to claim 24, and further comprising:
each secondary releasable fastening device including a threaded fastener assembly.

26. Apparatus according to claim 22, and further comprising:
a plurality of pairs of secondary releasable fastening devices each releasably engageable for selectively positioning opposite ends of a corresponding plurality of first locating members on a respective pair of second locating members.

27. Apparatus according to claim 1, and further comprising:
a supply of cooling air operable to provide cool air for cooling at least a portion of the primary PCB.

28. Apparatus according to claim 27, and further comprising:
the supply of cooling air including an air supply nozzle supported to provide cool air for cooling at least a portion of the primary PCB, the air supply nozzle being selectively positionable in relation to the primary PCB when the same is supported on the fixture frame.

29. Apparatus according to claim 28, and further comprising:
the supply of cooling air including a vortex tube cooling apparatus configured to receive primary compressed air from a primary supply, the vortex tube cooling apparatus being operable to produce cool air.

30. Apparatus according to claim 29, and further comprising:
at least one air filtration device connected to receive at least one of the primary compressed air and the cool air to filter impurities from the same prior to supplying the cool air to the primary PCB.

31. Apparatus according to claim 29, and further comprising:
the primary supply being a general supply of compressed air, the general supply of compressed air being supplied for general use in a facility where the apparatus is located.

32. Apparatus according to claim 29, and further comprising:
the supply of cooling air including a manifold connected downstream of the vortex tube vortex cooling apparatus, the manifold being operable to provide from operation of a single vortex tube cooling apparatus cool air to multiple identical apparatus.

33. Apparatus according to claim 27, and further comprising:
the supply of cooling air operable to provide cool air for cooling at least a portion of the primary PCB to compensate for cooling effects produced by a heat sink located in a native computing device.

34. Apparatus according to claim 1, and further comprising:
a plurality of mating connector members configured to be connected to corresponding of the plurality of on-board interconnects to establish wired connections to respective of a plurality of off-board peripherals when the primary PCB is supported on the fixture frame.

35. Apparatus according to claim 34, and further comprising:
the plurality of wired connections to off-board peripherals from the primary PCB mimicking architecture of a native computing device when the primary PCB is supported on the fixture frame.

36. Apparatus according to claim 34, and further comprising:
the plurality of off-board peripherals including an off-board power supply.

37. Apparatus according to claim 36, and further comprising:
the off-board power supply being a native battery, the native battery being compatible with the native computing device.

38. Apparatus according to claim 37, and further comprising:
a battery connector extension cable, the battery connector extension cable including a first mating battery pinout connector suitable for mating connection with a certain native battery pinout connector, the battery connector extension cable including a replicated native battery pinout connector suitable for connection to a native battery replica, the battery connector extension cable including a wired battery cable intermediate the first mating battery pinout connector and replicated native battery pinout connector of suitable length to reach from the native battery replica to the primary PCB supported on the fixture frame, the wired battery cable configured to meet specifications for conveying power from the battery to the primary PCB, the wired battery cable configured to meet specifications for communicating data between the battery and primary PCB to enable proper operation of the battery to mimic a native battery.

39. Apparatus according to claim 34, and further comprising:
a plurality of peripheral interconnect extension cables, each peripheral interconnect extension cable including a replicated native mating peripheral pinout connector suitable for connecting in mating relationship with a corresponding on-board interconnect peripheral pinout, each peripheral interconnect extension cable including a remote replicated peripheral pinout connector identical to the corresponding on-board interconnect for connecting in mating relationship with a corresponding replicated native off-board peripheral device, and a suitable interconnect extension cable intermediate the replicated native mating peripheral pinout connector and remote replicated peripheral pinout connector.

40. Apparatus according to claim 34, and further comprising:
an off-board display supported in proximity to the fixture frame for temporary connection to the primary PCB, the plurality of on-board interconnects including a display connector, the display connector configured to be connected to the off-board display.

41. Apparatus according to claim 34, and further comprising:
an off-board operator input device supported in proximity to the fixture frame for temporary connection to the primary PCB, the plurality of on-board interconnects including an operator input device connector, the operator input device connector configured to be connected to the off-board operator input device.

42. Apparatus according to claim 34, and further comprising:
the off-board operator input device including at least one of the following:
a set of input keys, a key emulator, a keyboard, and a keyboard emulator.

43. A method for testing in series a plurality of disparate primary PCB's, the primary PCB's originating in disparate native computing devices, each primary PCB having a plurality of mounting holes arranged in spaced relation in a board plane, the plurality of mounting holes of disparate primary PCB's being located at different mounting hole locations corresponding to respective of the primary PCB's, said method comprising the steps of:
providing apparatus for testing a primary PCB, the apparatus including a plurality of fixture mounting posts supported by a fixture frame, the fixture mounting posts being selectively positionable in a mounting plane relative to the fixture frame;
positioning a primary PCB adjacent to the fixture frame with the board plane in substantially parallel relation to the mounting plane, the primary PCB being free of the primary housing;
identifying among mounting hole locations on the primary PCB at least three identified mounting hole locations;
locating on the fixture frame a plurality of fixture mounting post locations aligned with the at least three identified mounting hole locations;
fastening a plurality of fixture mounting posts in the mounting plane at respective of the at least three identified mounting hole locations by manually placing a base of each fixture mounting post in a releasably fastened relationship with the fixture frame at each of the at least three identified mounting hole locations;
securing in each of the at least three identified mounting hole locations a distal end of a respective fixture mounting post;
connecting to a plurality of on-board interconnects a corresponding plurality of off-board peripherals connected thereto by respective wired connections, the plurality of off-board peripherals including an off-board power supply, the plurality of off-board peripherals including an off-board display, the plurality of off-board peripherals including a user data input device;
performing test procedures on the primary PCB;
removing from the test apparatus the primary PCB; and
repeating for each primary PCB the steps of providing, positioning, identifying, locating, fastening, securing, connecting, performing and removing.

44. A method for testing according to claim 43, and further comprising:
cooling at least a portion of the primary PCB when performing test procedures on the same.

45. A method for testing according to claim 44, and further comprising:
in the step of cooling, cooling air being provided from a nozzle associated with the fixture frame for cooling at least a portion of the primary PCB.

46. A method for testing according to claim 45, and further comprising:
in the step of cooling, the cooling air being provided from a nozzle in communication with a supply of cooling air, the supply of cooling air including a vortex tube cooling apparatus configured to receive primary compressed air from a primary supply, the vortex tube cooling apparatus being operable to produce cool air.

47. Apparatus according to claim 46, and further comprising:
in the step of cooling, the primary supply being a general supply of compressed air, the general supply of compressed air being supplied for general use in a facility where the apparatus is located.

48. Apparatus according to claim 1, and further comprising:
a universal test fixture enclosure dimensioned to cooperate with the fixture frame to at least partially enclose an area about the primary PCB to substantially define a temperature controlled zone about the primary PCB.
